(19) United States
(12) Patent Application Publication
(10) Pub. No.: US 2025/0374713 A1
(43) Pub. Date: Dec. 4, 2025

(54) SURFACE EMITTING ELEMENT

(71) Applicant: SONY SEMICONDUCTOR SOLUTIONS CORPORATION, KANAGAWA (JP)

(72) Inventor: HIDEKAZU AOYAGI, KUMAMOTO (JP)

(21) Appl. No.: 18/867,827

(22) PCT Filed: Apr. 6, 2023
(86) PCT No.: PCT/JP2023/014230

§ 371 Date: Nov. 21, 2024

(30) Foreign Application Priority Data
May 30, 2022 (JP) 2022-087621

(51) Int. Cl. H10H 20/816; H01S 5/042; H01S 5/183; H01S 5/42; H10H 20/813

(52) U.S. Cl. CPC H10H 20/816; H01S 5/04256; H01S 5/18311; H01S 5/1835; H01S 5/423; H10H 20/813

(57) ABSTRACT

To provide a surface emitting element having a current injection structure capable of suppressing vignetting and absorption of light. A surface emitting element according to the present technology includes: a multilayer structure including a first semiconductor structure and a second semiconductor structure stacked with each other, and a light emitting layer disposed between the first semiconductor structure and the second semiconductor structure and having a light emitting region, in which in the second semiconductor structure, at least a surface layer on a side opposite to the light emitting layer side has a first region corresponding to the light emitting region and a second region that is a surrounding region of the first region and has lower resistance than the first region. According to the surface emitting element according to the present technology, it is possible to provide a surface emitting element having a current injection structure capable of suppressing vignetting and absorption of light.

### TECHNICAL FIELD

The technology according to the present disclosure (hereinafter also referred to as “the present technology”) relates to a surface emitting element.

### BACKGROUND ART

Conventionally, a surface emitting element (for example, a surface emitting laser, a light emitting diode, or the like) in which a guiding direction of light and a conduction direction of a current are substantially the same is known.

Some conventional surface emitting elements have an electrode (current injection structure) including at least one metal for injecting a current into a light emitting layer on an optical waveguide and/or near the optical waveguide (see, for example, Patent Documents 1 and 2.).

### CITATION LIST

### Patent Document

Patent Document 1: Japanese Patent Application Laid-Open No. 2006-66482

Patent Document 2: Japanese Patent Application Laid-Open No. 7-202313

### SUMMARY OF THE INVENTION

### Problems to be Solved by the Invention

In a conventional surface emitting element, vignetting or absorption of light by an electrode occurs.

Therefore, a main object of the present technology is to provide a surface emitting element having a current injection structure capable of suppressing vignetting and absorption of light.

### Solutions to Problems

The present technology provides a surface emitting element including:
a multilayer structure including a first semiconductor structure and a second semiconductor structure stacked with each other, and
a light emitting layer disposed between the first semiconductor structure and the second semiconductor structure and having a light emitting region, in which
in the second semiconductor structure, at least a surface layer on a side opposite to the light emitting layer side has a first region corresponding to the light emitting region and a second region that is a surrounding region of the first region and has lower resistance than the first region.

The multilayer structure may be provided with a current confinement region for setting the light emitting region.

The second region may have a higher impurity concentration than the first region.

An electrode may be provided on the second region.

The second region may have an extending portion extending in an in-plane direction from the first region side, and the electrode may be installed on the extending portion.

The second region may have a circling portion surrounding the first region.

The surface emitting element according to claim 1, in which
the multilayer structure includes a substrate disposed on a side opposite to the light emitting layer side of the first semiconductor structure, and
at least a surface layer of the substrate on the first semiconductor structure side and/or at least a surface layer of the first semiconductor structure on the substrate side have a low resistance region.

The low resistance region may have a higher impurity concentration than a surrounding region thereof.

The low resistance region may be provided around a region of the first semiconductor structure corresponding to the light emitting region.

An electrode may be installed on the low resistance region.

The multilayer structure may have another low resistance region connected to the low resistance region.

The another low resistance region may have a higher impurity concentration than a surrounding region thereof.

The multilayer structure may have a mesa on the substrate, the mesa having an electrode placed on a top, and the another low resistance region may extend at least inside the mesa in a stacking direction, and have one end connected to the low resistance region and the other end connected to the electrode.

The multilayer structure may have a mesa including the light emitting region on the substrate, and the another low resistance region may extend inside the mesa in a stacking direction, and have one end connected to the second region and the other end connected to the low resistance region.

The low resistance region and the another low resistance region may be of the same conductivity type.

The first region and the second region may be of different conductivity types.

The first semiconductor structure and the first region may be of the same conductivity type.

At least one of the first semiconductor structure and the second semiconductor structure may include a reflecting mirror.

The light emitting layer may have a plurality of the light emitting regions arranged in an in-plane direction.

When two directions intersecting with each other in a plane orthogonal to a stacking direction are referred to as a first direction and a second direction, the substrate and/or the first semiconductor structure may include a plurality of the low resistance regions each extending along the first direction and arranged along the second direction, the second semiconductor structure may include a plurality of the second regions each extending along the second direction and arranged along the first direction, and the light emitting region may be located on an intersection of each of the low resistance regions and each of the second regions when viewed from the stacking direction.

### BRIEF DESCRIPTION OF DRAWINGS

FIG. 1A is a plan view of a surface emitting element according to a first embodiment of the present technology, and

FIG. 1B is a cross-sectional view of the surface emitting element according to the first embodiment of the present technology.

FIG. 2 is a flowchart for explaining an example of a method for manufacturing the surface emitting element according to the first embodiment of the present technology.

FIGS. 3A and 3B are a cross-sectional view and a plan view, respectively, for each step of the example of the method for manufacturing the surface emitting element according to the first embodiment of the present technology.

FIGS. 4A and 4B are a cross-sectional view and a plan view, respectively, for each step of the example of the method for manufacturing the surface emitting element according to the first embodiment of the present technology.

FIGS. 5A and 5B are a cross-sectional view and a plan view, respectively, for each step of the example of the method for manufacturing the surface emitting element according to the first embodiment of the present technology.

FIGS. 6A and 6B are a cross-sectional view and a plan view, respectively, for each step of the example of the method for manufacturing the surface emitting element according to the first embodiment of the present technology.

FIGS. 7A and 7B are a cross-sectional view and a plan view, respectively, for each step of the example of the method for manufacturing the surface emitting element according to the first embodiment of the present technology.

FIGS. 8A and 8B are a cross-sectional view and a plan view, respectively, for each step of the example of the method for manufacturing the surface emitting element according to the first embodiment of the present technology.

FIGS. 9A and 9B are a cross-sectional view and a plan view, respectively, for each step of the example of the method for manufacturing the surface emitting element according to the first embodiment of the present technology.

FIGS. 10A and 10B are a cross-sectional view and a plan view, respectively, for each step of the example of the method for manufacturing the surface emitting element according to the first embodiment of the present technology.

FIG. 11 is a cross-sectional view of a surface emitting element according to Example 1 of the first embodiment of the present technology.

FIG. 12 is a cross-sectional view of a surface emitting element according to Example 2 of the first embodiment of the present technology.

FIG. 13 is a cross-sectional view of a surface emitting element according to Example 3 of the first embodiment of the present technology.

FIG. 14 is a cross-sectional view of a surface emitting element according to Example 4 of the first embodiment of the present technology.

FIG. 15A is a plan view of a surface emitting element according to a second embodiment of the present technology, and

FIG. 15B is a cross-sectional view of the surface emitting element according to the second embodiment of the present technology.

FIG. 16 is a cross-sectional view of a surface emitting element according to Example 1 of the second embodiment of the present technology.

FIG. 17 is a cross-sectional view of a surface emitting element according to Example 2 of the second embodiment of the present technology.

FIG. 18 is a cross-sectional view of a surface emitting element according to Example 3 of the second embodiment of the present technology.

FIG. 19 is a cross-sectional view of a surface emitting element according to Example 4 of the second embodiment of the present technology.

FIG. 20A is a plan view of a surface emitting element according to a third embodiment of the present technology, and

FIG. 20B is a cross-sectional view of the surface emitting element according to the third embodiment of the present technology.

FIG. 21 is a cross-sectional view of a surface emitting element according to Example 1 of the third embodiment of the present technology.

FIG. 22 is a cross-sectional view of a surface emitting element according to Example 2 of the third embodiment of the present technology.

FIG. 23 is a cross-sectional view of a surface emitting element according to Example 3 of the third embodiment of the present technology.

FIG. 24 is a cross-sectional view of a surface emitting element according to Example 4 of the third embodiment of the present technology.

FIG. 25A is a plan view of a surface emitting element according to a fourth embodiment of the present technology, and

FIG. 25B is a cross-sectional view of the surface emitting element according to the fourth embodiment of the present technology.

FIG. 26 is a cross-sectional view of a surface emitting element according to Example 1 of the fourth embodiment of the present technology.

FIG. 27 is a cross-sectional view of a surface emitting element according to Example 2 of the fourth embodiment of the present technology.

FIG. 28 is a cross-sectional view of a surface emitting element according to Example 3 of the fourth embodiment of the present technology.

FIG. 29 is a cross-sectional view of a surface emitting element according to Example 4 of the fourth embodiment of the present technology.

FIG. 30 is a sectional view of a surface emitting element according to a fifth embodiment of the present technology.

FIG. 31A is a cross-sectional view (part 1) of the surface emitting element according to the fifth embodiment of the present technology. FIG. 31B is a cross-sectional view (part 2) of the surface emitting element according to the fifth embodiment of the present technology.

FIG. 32 is a cross-sectional view of a surface emitting element according to Modification 1 of the first embodiment of the present technology.

FIG. 33 is a cross-sectional view of a surface emitting element according to Modification 2 of the first embodiment of the present technology.

FIG. 34 is a cross-sectional view of a surface emitting element according to Modification 3 of the first embodiment of the present technology.

FIG. 35 is a cross-sectional view of a surface emitting element according to Modification 4 of the first embodiment of the present technology.

FIG. 36 is a cross-sectional view of a surface emitting element according to Modification 5 of the first embodiment of the present technology.

FIG. 37 is a cross-sectional view of a surface emitting element according to Modification 1 of the second embodiment of the present technology.

FIG. 38 is a cross-sectional view of a surface emitting element according to Modification 2 of the second embodiment of the present technology.

FIG. 39 is a cross-sectional view of a surface emitting element according to Modification 3 of the second embodiment of the present technology.

FIG. 40 is a cross-sectional view of a surface emitting element according to Modification 1 of the third embodiment of the present technology.

FIG. 41 is a cross-sectional view of a surface emitting element according to Modification 2 of the third embodiment of the present technology.

FIG. 42 is a cross-sectional view of a surface emitting element according to Modification 1 of the fourth embodiment of the present technology.

FIG. 43 is a cross-sectional view of a surface emitting element according to Modification 2 of the fourth embodiment of the present technology.

FIG. 44 is a cross-sectional view of a surface emitting element according to Modification 3 of the fourth embodiment of the present technology.

FIG. 45 is a cross-sectional view of a surface emitting element according to a modification of the present technology.

FIG. 46 is a cross-sectional view of a surface emitting element according to a modification of the present technology.

FIG. 47 is a view illustrating an application example of the surface emitting element according to the first embodiment of the present technology to a distance measuring device.

FIG. 48 is a block diagram illustrating an example of a schematic configuration of a vehicle control system.

FIG. 49 is an explanatory diagram illustrating an example of installation positions of distance measurement devices.

### MODE FOR CARRYING OUT THE INVENTION

Hereinafter, preferred embodiments of the present technology will be described in detail with reference to the accompanying drawings. Note that, in the present specification and drawings, components having substantially the same functional configuration are denoted by the same reference signs, and redundant description is omitted. The embodiments to be described below provide representative embodiments of the present technology, and the scope of the present technology is not to be narrowly interpreted according to those embodiments. In the present specification, even in a case where it is described that the surface emitting element according to the present technology exhibits a plurality of effects, the surface emitting element according to the present technology is only required to exhibit at least one effect. The effects described in the present specification are merely examples and are not limited, and other effects may be exerted.

Furthermore, the description will be given in the following order.
0. Introduction
1. Surface emitting element according to first embodiment of present technology
2. Surface emitting element according to second embodiment of present technology
3. Surface emitting element according to third embodiment of present technology
4. Surface emitting element according to fourth embodiment of present technology
5. Surface emitting element according to fifth embodiment of present technology
6. Modification of present technology
7. Application example to electronic device
8. Example in which surface emitting element is applied to distance measuring device>
9. Example in which distance measuring device is mounted on mobile body

### 0. Introduction

Conventionally, there has been known a surface emitting element in which a waveguide direction of light and a conduction direction of a current are substantially the same, and an electrode (current injection structure) including at least one metal for injecting a current is provided on an optical waveguide and/or in the vicinity of the optical waveguide (see, for example, Patent Documents 1 and 2.).

However, in the conventional surface emitting element, light may be refracted (vignetted) or absorbed in an unintended direction by the electrode.

Therefore, after intensive studies, the inventor has devised the surface emitting element according to the present technology as a surface emitting element having a current injection structure capable of suppressing vignetting and absorption of light.

Hereinafter, some embodiments of the surface emitting element according to the present technology will be described in detail.

### 1. Surface Emitting Element According to First Embodiment of Present Technology

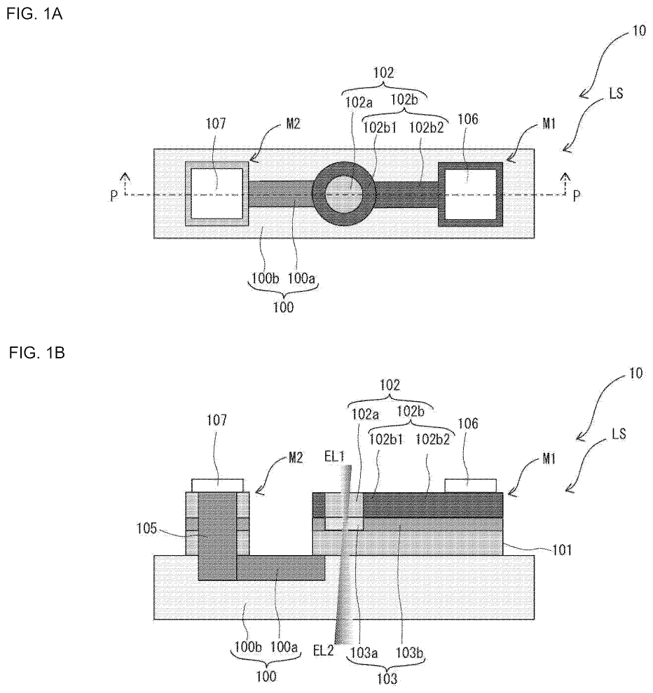

FIG. 1A is a plan view of a surface emitting element 10 according to a first embodiment of the present technology. FIG. 1B is a cross-sectional view of the surface emitting element 10 according to the first embodiment of the present technology. FIG. 1B is a cross-sectional view taken along line P-P in FIG. 1A. Hereinafter, in the cross-sectional view of FIG. 1B and the like, an upper side will be described as “upper” and a lower side will be described as “lower” as appropriate.

### Configuration of Surface Emitting Element

### Overall Configuration

As illustrated in FIGS. 1A and 1B as an example, the surface emitting element 10 according to a first embodiment of the present technology includes a multilayer structure LS including first and second semiconductor structures 101 and 102 stacked with each other, and a light emitting layer 103 having a light emitting region 103a disposed between the first and second semiconductor structures 101 and 102. As an example, the light emitting layer 103 includes a compound semiconductor having band gap energy smaller than those of the first and second semiconductor structures 101 and 102. Hereinafter, the direction in which the first and second semiconductor structures 101 and 102 are stacked with each other is also referred to as a “stacking direction”.

The surface emitting element 10 is driven by a driver as an example. As an example, the driver includes a power source and a transistor that controls on/off of energization from the power source to the surface emitting element 10.

In the multilayer structure LS, as an example, a current confinement region 103b for setting the light emitting region 103a is provided. As an example, the current confinement region 103b is a region surrounding the light emitting region 103a of the light emitting layer 103. That is, as an example, the light emitting layer 103 has the current confinement region 103b around the light emitting region 103a. The current confinement region 103b is a region including an insulating material or a high-resistance material and having extremely low carrier conductivity (including 0). The inner peripheral shape of the current confinement region 103b is, for example, a circular shape, but may be another shape such as an elliptical shape or a polygonal shape. Here, the outer peripheral shape of the light emitting region 103a is a shape corresponding to the inner peripheral shape of the current confinement region 103b. Examples of the current confinement region 103b include an oxidation confinement region, an ion implantation region, and the like.

The second semiconductor structure 102 is a current injection structure having an electrode contact region. As an example, in the second semiconductor structure 102, at least the surface layer (for example, the entire region in the thickness direction) on the opposite side to the light emitting layer 103 side has a first region 102a corresponding to the light emitting region 103a and a second region 102b that is a surrounding region of the first region 102a and has a lower resistance than the first region 102a. As an example, the diameter of the first region 102a substantially matches the current confinement diameter of the current confinement region 103b (the diameter of the light emitting region 103a).

The outer peripheral shape of the first region 102a is preferably substantially the same as the inner peripheral shape of the current confinement region 103b, and is circular as an example, but may be other shapes such as an elliptical shape and a polygonal shape. As an example, the diameter of the first region 102a substantially coincides with the current confinement diameter (the diameter of the light emitting region 103 a) of the current confinement region 103b.

As an example, the second region 102b is a highly doped region having an impurity concentration (doping concentration) higher than that of the first region 102a. The highly doped region is advantageous for reducing the resistance as the cross-sectional area is larger.

As an example, the second region 102b includes a circling portion 102b1 surrounding the first region 102a. The plan view shape of the circling portion 102b1 is, for example, a frame shape such as an annular shape. The second region 102b has an extending portion 102b2 extending in the in-plane direction (for example, the P-P line direction in FIG. 1A) from the first region 102a side. The extending portion 102b2 substantially functions as a wiring. As an example, one end portion of the extending portion 102b2 is connected to the circling portion 102b1, and the other end portion is an electrode installation portion (electrode contact region).

The shape of the electrode installation portion is a square as an example, but may be another shape such as a circle, an ellipse, or a polygon other than a square.

The electrode 106 is installed on the second region 102b. More specifically, the electrode 106 is installed on the extending portion 102b2 of the second region 102b. As an example, the electrode 106 is installed on an electrode installation portion which is the other end portion of the extending portion 102b2. That is, the electrode 106 is installed at a position away from an optical waveguide passing through the center of the light emitting region 103a and extending in the stacking direction.

The multilayer structure LS includes a substrate 100 disposed on a side opposite to the light emitting layer 103 side of the first semiconductor structure 101, and in the substrate 100, at least a surface layer on the first semiconductor structure 101 side has a low resistance region 100a having a lower resistance than a surrounding region 100b. The low resistance region 100a has a higher impurity concentration than the surrounding region 100b.

The low resistance region 100a is provided around a region of the substrate 100 corresponding to the light emitting region 103a. That is, the low resistance region 100a is connected to the first semiconductor structure 101 of a first mesa M1 described later and is provided at a position away from the optical waveguide.

The multilayer structure LS has the another low resistance region 105 connected to the low resistance region 100a. The another low resistance region 105 is a highly doped region having a higher impurity concentration (doping concentration) than the surrounding region. The highly doped region is advantageous for reducing the resistance as the cross-sectional area is larger.

The multilayer structure LS has the first mesa M1 including the light emitting region 103a and a second mesa M2 in which an electrode 107 is installed on the top, the first mesa M1 and the second mesa M2 being arranged to be spaced apart from each other in the in-plane direction on the substrate 100. As an example, the first and second mesas M1 and M2 have substantially the same height (for example, about 4 to 6 μm). The first mesa M1 is also referred to as a “luminescent mesa”. The second mesa M2 is also referred to as a “pedestal portion” or a “dummy mesa”. Hereinafter, for convenience, the electrode 107 is also referred to as a first electrode 107, and the electrode 106 is also referred to as a second electrode 106.

The another low resistance region 105 extends at least inside the second mesa M2 in the stacking direction, and has one end (lower end) connected to the low resistance region 100a and the other end (upper end) connected to the electrode 107. The another low resistance region 105 is a highly doped region having an impurity concentration (doping concentration) higher than that of a surrounding region of the another low resistance region 105 of the second mesa M2. The highly doped region is advantageous for reducing the resistance as the cross-sectional area is larger. The other end (upper end) of the another low resistance region 105 is an electrode contact region.

### Conductivity Type

As an example, the surface emitting element 10 has the following conductivity type. The first semiconductor structure 101 of the first and second mesas M1 and M2 is of a first conductivity type. In the second semiconductor structure 102 of the first mesa M1, the conductivity types of the first and second regions 102a and 102b are different. In the second semiconductor structure 102 of the first mesa M1, the first region 102a is of the first conductivity type, and the second region 102b is of a second conductivity type. That is, the first semiconductor structure 101 and the first region 102a of the second semiconductor structure 102 are of the same conductivity type. The second semiconductor structure 102 of the second mesa M2 is of the first conductivity type. The low resistance region 100a and the another low resistance region 105 are of the same first conductivity type. One of the first and second conductivity types is of a p-type, and the other is of an n-type.

### Electrode

Of the electrodes 106 and 107, an electrode in contact with the p-type semiconductor is an anode electrode (p-side electrode), and an electrode in contact with the n-type semiconductor is a cathode electrode (n-side electrode). The anode electrode is connected to the anode side of the driver, and the cathode electrode is connected to the cathode side of the driver. Examples of the material of the electrode 106, 107 include Au/Ni/AuGe and Au/Pt/Ti.

### Impurity

Examples of the p-type impurity (dopant) include Zn, Mg, Be, and C. Examples of the n-type impurity (dopant) include Si, Se, and Ge. The doping concentration of each highly doped region is set to, for example, a concentration (for example, 1×18 cm⁻³ or more) at which carrier conductivity (conductivity) is equal to or higher than that of a metal used for normal wiring.

The surface emitting element 10 configured as described above has a double heterostructure in which the light emitting layer 103 is sandwiched between the first and second semiconductor structures 101 and 102 of different conductivity types in the stacking direction, and in principle, the light from the light emitting layer 103 can be emitted to at least one side in the stacking direction. That is, it is possible to obtain a surface emission output.

### Emission Type, Mounting Method

The surface emitting element 10 can be mounted on a driver in, for example, a junction-down manner (flip chip). In a case where the surface emitting element 10 is mounted on the driver in a junction-down manner, the surface emitting element is substantially a back surface emission type surface emitting element that emits light to the back surface (lower surface) side. In particular, in the surface emitting element 10, since the two electrodes 106 and 107 are installed at substantially the same height, it is suitable for use as a back surface emission type surface emitting element mounted in a junction-down manner.

Note that the surface emitting element 10 may be mounted on the driver in, for example, a junction-up manner (for example, wire bonding). In a case where mounted on the driver in a junction-up manner, the surface emitting element 10 is substantially a surface emission type surface emitting element that emits light to the surface (upper surface) side.

At least one of the first and second semiconductor structures 101 and 102 may include a reflecting mirror (for example, a multilayer film reflecting mirror). For example, in a case where one of the first and second semiconductor structures 101 and 102 includes a reflecting mirror, the surface emitting element 10 can function as a high-efficiency light emitting diode that emits light to one surface side (opposite side to the reflecting mirror side). For example, in a case where both the first and second semiconductor structures 101 and 102 include a reflecting mirror, the surface emitting element 10 can be caused to function as a surface emitting laser (vertical cavity surface emission type laser (VCSEL)).

For example, in a case where both the first and second semiconductor structures 101 and 102 do not include a reflecting mirror (for example, a multilayer film reflecting mirror), the surface emitting element 10 is a light emitting diode that emits light to both sides. In this case, for example, it is also possible to use only the light emitted on one side, but for example, it is also possible to use light emitted on the side opposite to the emission side as monitor light for monitoring the light amount by providing the light receiving element at an appropriate position of the driver.

### Materials of Substrate, Light Emitting Layer, and First and Second Semiconductor Structures

As the substrate 100, for example, a semiconductor substrate including an impurity semiconductor or an intrinsic semiconductor, a semi-insulating substrate, an insulating substrate, or the like can be used. As a material of the light emitting layer 103, a compound semiconductor corresponding to a desired emission wavelength can be used. In particular, in a case where the surface emitting element 10 is used as a back surface emission type, the substrate 100 is required to be transparent to the emission wavelength of the light emitting layer 103. In this case, in the combination of the materials of the substrate 100 and the light emitting layer 103, for example, the material of the substrate 100 may be GaAs, InP, and Ge, and the material of the light emitting layer 103 may be GaAs-based (for example, GaAs, AlGaAs, GaInAs, GaInAsN, or the like). For example, the material of the substrate 100 may be InP, Ge, or Si, and the material of the light emitting layer 103 may be, for example, AlGaInP, or the material of the substrate 100 may be Al₂O₃, and the material of the light emitting layer 103 may be ZnSSe or AlGaInN. The materials of the first and second semiconductor structures 101 and 102 and the light emitting layer 103 are preferably compound semiconductors lattice-matched to the substrate 100 or another substrate.

### Operation of Surface Emitting Element

Hereinafter, the operation of the surface emitting element 10 will be described. As an example, the operation of the back surface emission type surface emitting element 10 in which the second electrode 106 is an anode electrode (p-side electrode), the first electrode 107 is a cathode electrode (n-side electrode), the first semiconductor structure 101 is of an n-type, the first region 102a of the second semiconductor structure 102 is of an n-type, and the second region 102b of the second semiconductor structure 102 is of a p-type with low resistance will be described. In the surface emitting element 10, a current from the anode side of the driver flows into the electrode installation portion of the extending portion 102b2 of the second region 102b (highly doped region) via the electrode 106. The current flowing into the electrode installation portion flows toward the circling portion 102b1 along the extending direction (for example, the P-P line direction) of the extending portion 102b2, and flows into the first region 102a from the circling portion 102b1. The current flowing into the first region 102a flows into the light emitting region 103a while being narrowed in the current confinement region 103b. At this time, the light emitting region 103a emits light, and a surface emission output is obtained. The current that has passed through the light emitting region 103a flows into the low resistance region 100a (highly doped region) via the first semiconductor structure 101 of the first mesa M1. The current flowing into the low resistance region 100a flows toward the another low resistance region 105 (highly doped region) in the low resistance region 100a, and flows into the another low resistance region 105. The current flowing into the another low resistance region 105 flows toward the electrode 107 along the height direction of the second mesa M2 in the another low resistance region 105, and flows out to the cathode side of the driver via the electrode 107.

### Method for Manufacturing Surface Emitting Element

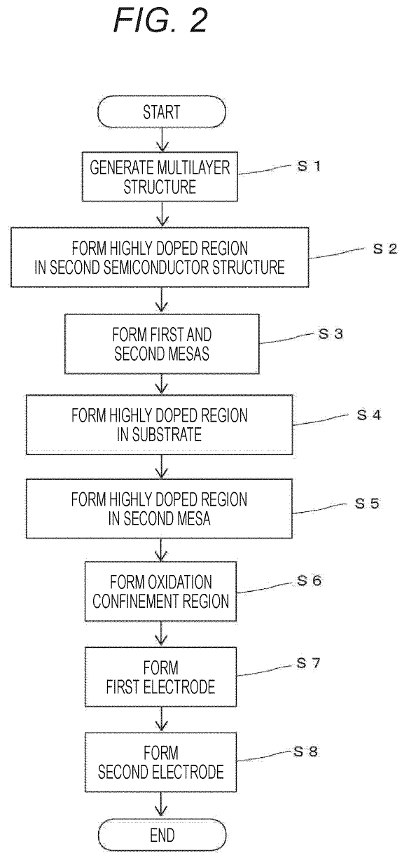

Hereinafter, a method for manufacturing the surface emitting element 10 will be described with reference to the flowchart and the like of FIG. 2. As an overall flow, first, a plurality of surface emitting elements 10 is simultaneously generated on one wafer (hereinafter, referred to as a “substrate 100” for convenience.) which is a base material of the substrate 100 by a semiconductor manufacturing method using a semiconductor manufacturing apparatus. Next, the plurality of continuous integrated surface emitting elements 10 is separated from each other by dicing to obtain a chip-shaped surface emitting element 10. Here, the first and second semiconductor structures 101 and 102 and the light emitting layer 103 include a compound semiconductor lattice-matched to the material of the substrate 100.

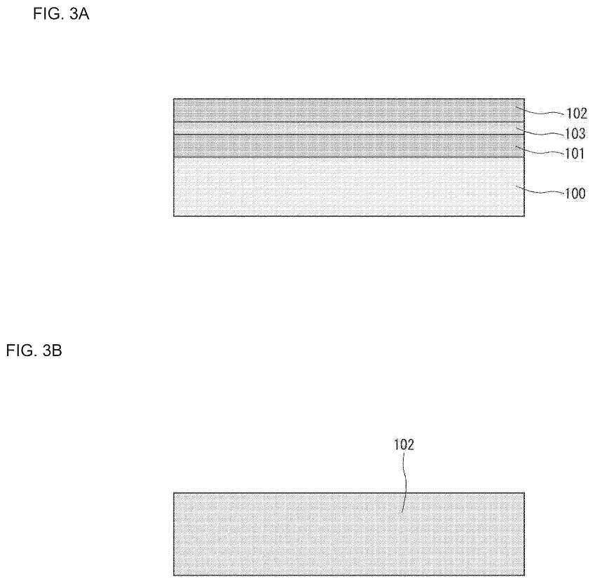

In the first step S1, a multilayer structure is generated (see FIGS. 3A and 3B). Specifically, for example, the first semiconductor structure 101 of the first conductivity type, the light emitting layer 103, and the second semiconductor structure 102 of the first conductivity type are stacked in this order on the substrate 100 as a growth substrate by an epitaxial crystal growth method such as a metal organic chemical vapor deposition (MOCVD) method to generate a multilayer structure. At this time, as raw materials of the compound semiconductor, for example, a methyl-based organometallic gas such as trimethylaluminum (TMAl), trimethylgallium (TMGa), or trimethylindium (TMIn) and an arsine (AsH₃) gas are used, as raw materials of donor impurities, for example, disilane (Si₂H₆) is used, and as raw materials of acceptor impurities, for example, carbon tetrabromide (CBr₄) is used.

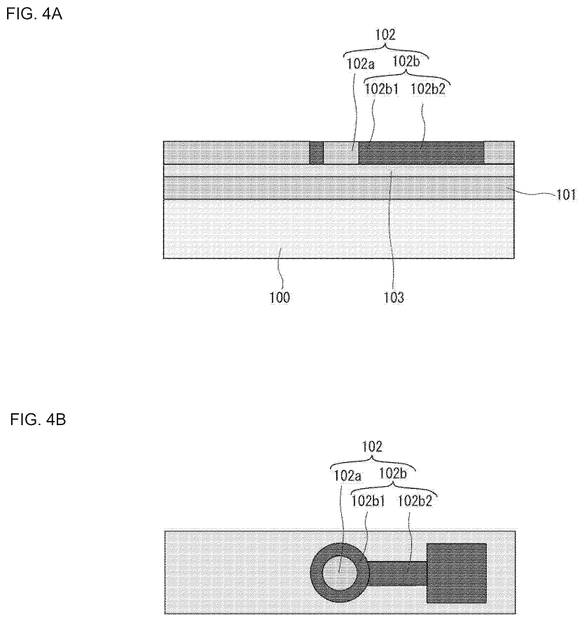

In the next step S2, a highly doped region as the second region 102b is formed in the second semiconductor structure 102 (FIGS. 4A and 4B). Specifically, a resist pattern opened at a portion where the second region 102b is to be formed is formed on the multilayer structure (on the second semiconductor structure 102) by photolithography, and the impurity of the second conductivity type is implanted into the second semiconductor structure 102 at a high concentration using the resist pattern as a mask. The impurity implantation depth at this time is, for example, up to a boundary position between the second semiconductor structure 102 and the light emitting layer 103. Thereafter, the resist pattern is removed.

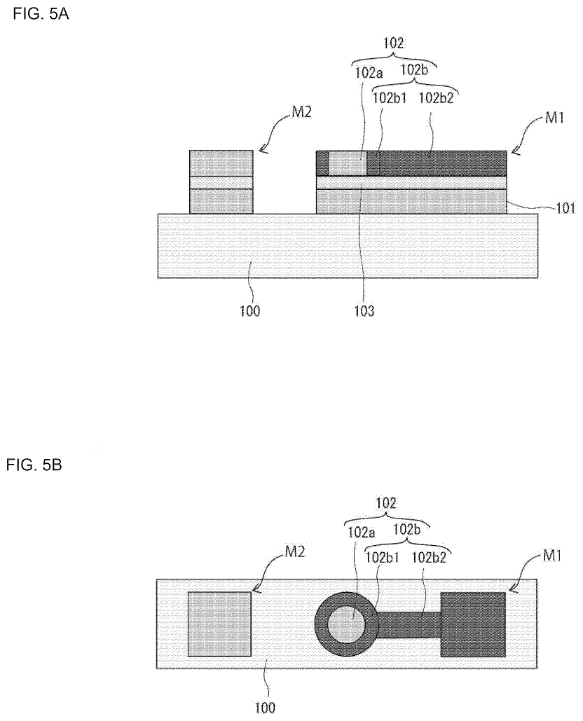

In the next step S3, the first and second mesas M1 and M2 are formed (see FIGS. 5A and 5B). Specifically, a resist pattern covering a portion where the first and second mesas M1 and M2 are to be formed is formed on the multilayer structure on which the second region 102b is formed by photolithography, and the multilayer structure is etched by dry etching or wet etching using the resist pattern as a mask. The etching depth at this time is, for example, until the substrate 100 is exposed. Thereafter, the resist pattern is removed.

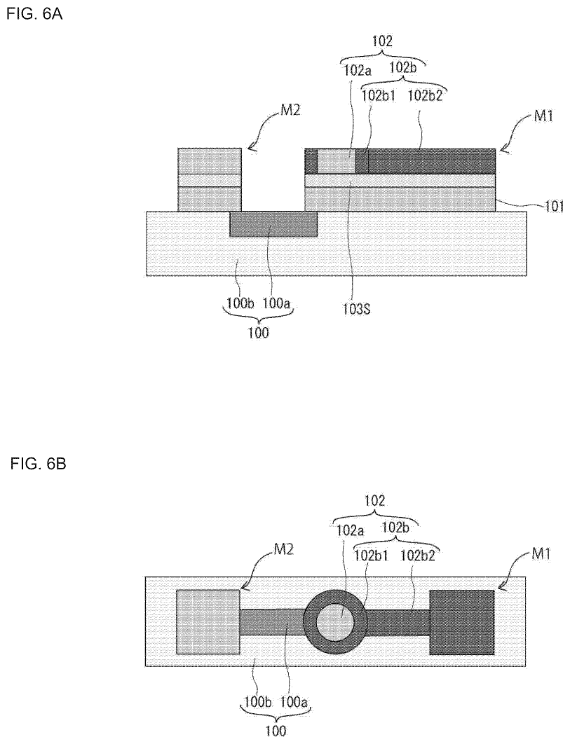

In the next step S4, a highly doped region as the low resistance region 100a is formed in the substrate 100 (see FIGS. 6A and 6B). Specifically, a resist pattern opened at a position where the low resistance region 100a is to be formed is formed on the multilayer structure in which the first and second mesas M1 and M2 are formed, and the impurity of the first conductivity type is implanted at a high concentration using the resist pattern as a mask. At this time, the impurity is preferably diffused below the first and second mesas M1 and M2 by controlling the impurity implantation direction. Thereafter, the resist pattern is removed.

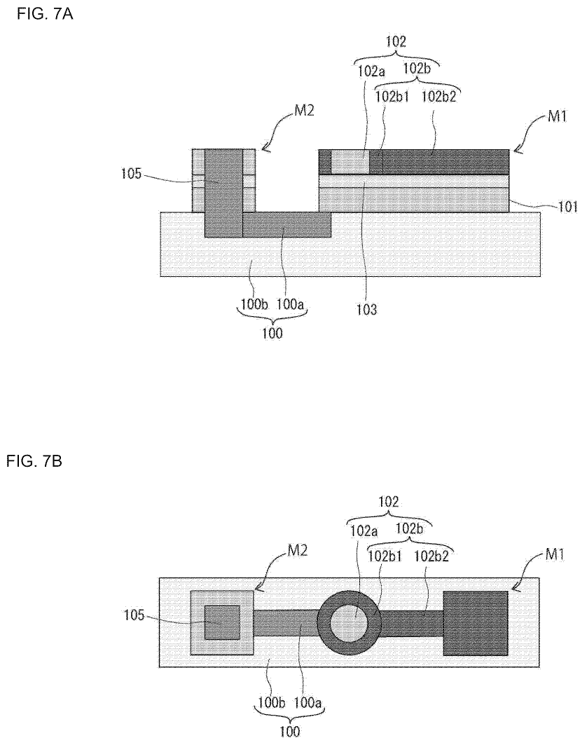

In the next step S5, a highly doped region as the another low resistance region 105 is formed in the second mesa M2 (see FIGS. 7A and 7B). Specifically, a resist pattern opened at the central portion of the top of the second mesa M2 of the multilayer structure on which the low resistance region 100a is formed is formed, and using the resist pattern as a mask, the impurity of the first conductivity type (for example, the same impurity as the impurity of the low resistance region 100a) is implanted at a high concentration. The impurity implantation depth at this time is a depth penetrating the mesa M2, for example, a depth connected to the low resistance region 100a in the substrate 100. Thereafter, the resist pattern is removed.

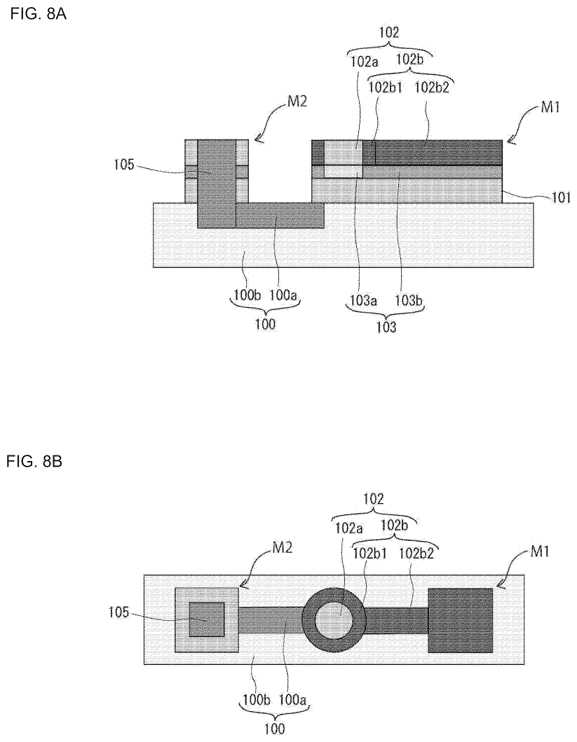

In the next step S6, an oxidation confinement region as the current confinement region 103b is formed (see FIGS. 8A and 8B). Specifically, the first and second mesas M1 and M2 are exposed to a high-temperature water vapor atmosphere, and the light emitting layer 103 is selectively oxidized from the side surface to form an oxidation confinement region as the current confinement region 103b surrounding the light emitting region 103a.

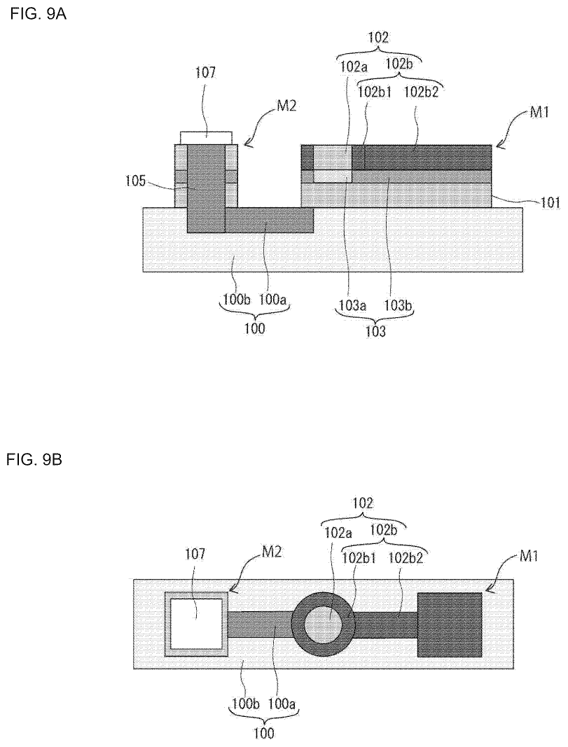

In the next step S7, the first electrode 107 is formed (see FIGS. 9A and 9B). Specifically, for example, the first electrode 107 is formed on the another low resistance region 105 exposed at the top of the second mesa M2 by a lift-off method. At this time, for example, vapor deposition, sputtering, or the like is used for film forming the electrode material.

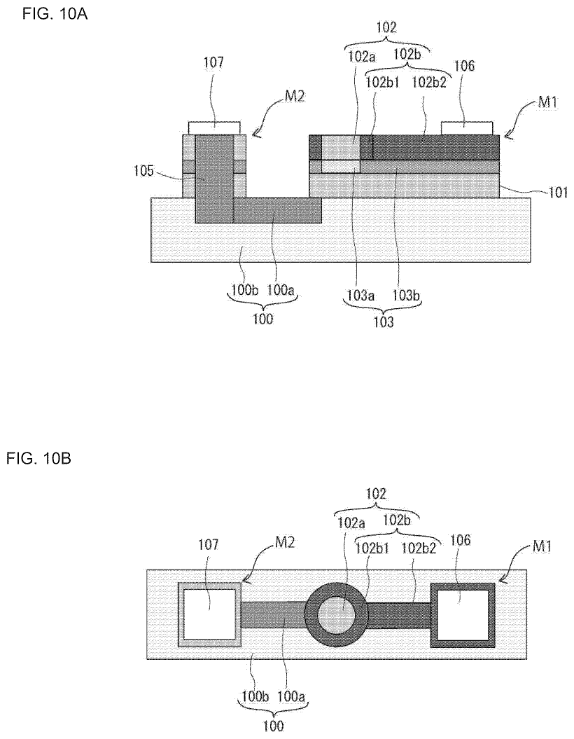

In the final step S8, the second electrode 106 is formed (see FIGS. 10A and 10B). Specifically, the second electrode 106 is formed on the electrode installation region of the second region 102b of the first mesa M1 by, for example, a lift-off method. At this time, for example, vapor deposition, sputtering, or the like is used for film forming the electrode material.

Note that, in the method for manufacturing the surface emitting element 10 described above, the low resistance region 100a is formed after the first semiconductor structure 101, the light emitting layer 103, and the second semiconductor structure 102 are stacked in this order on the substrate 100, but the present invention is not limited thereto. For example, a surface on the low resistance region 100a side of the substrate 100 (for example, a semiconductor substrate, a semi-insulating substrate, an insulating substrate, or the like) on which the low resistance region 100a is formed and a surface on the first semiconductor structure 101 side of a multilayer structure in which the second semiconductor structure 102, the light emitting layer 103, and the first semiconductor structure 101 are stacked in this order on another substrate (for example, a semiconductor substrate) may be aligned and joined.

### Effects of Surface Emitting Element

Hereinafter, effects of the surface emitting element 10 will be described. The surface emitting element 10 includes the multilayer structure LS including the first and second semiconductor structures 101 and 102 stacked to each other and the light emitting layer 103 having the light emitting region 103a disposed between the first and second semiconductor structures 101 and 102. In the second semiconductor structure 102, at least a surface layer on a side opposite to the light emitting layer 103 side has the first region 102a corresponding to the light emitting region 103a and the second region 102b that is a surrounding region of the first region 102a and has lower resistance than the first region 102a.

In this case, since a part of the second region 102b can be an electrode contact region, it is not necessary to provide an electrode in the first region 102a and/or in the vicinity of the first region 102a. That is, in the surface emitting element 10, it is possible to inject a current into the light emitting layer 103 without providing an electrode on the optical waveguide and/or in the vicinity of the optical waveguide.

As a result, according to the surface emitting element 10, it is possible to provide a surface emitting element having a current injection structure (second semiconductor structure 102) capable of suppressing vignetting and absorption of light. As a result, the beam quality and the light output can be improved.

The multilayer structure LS is provided with the current confinement region 103b for setting the light emitting region 103a. As a result, a current can be efficiently injected into the light emitting region 103a.

The second region 102b has a higher impurity concentration than the first region 102a. As a result, the second region 102b can be easily formed by impurity implantation (impurity diffusion).

The electrode 106 is installed on the second region 102b. In this case, the electrode 106 and the first region 102a can be electrically connected with good conductivity without using wiring. Since the wiring is not used, defects such as disconnection of the wiring do not occur. The absence of the wiring leads to a reduction in manufacturing cost and an improvement in productivity because a complicated wiring forming process of stacking a metal film and an insulating film can be omitted. Since the wiring is not used, an installation space for the wiring is unnecessary, so that the first mesas M1 can be arranged in an array with high density.

The second region 102b has the circling portion 102b1 surrounding the first region 102a. As a result, the current density of the current injected into the light emitting region 103a can be substantially uniformized.

The second region 102b has the extending portion 102b2 extending in the in-plane direction from the first region 102a side, and the electrode 106 is installed on the extending portion 102b2. The extending portion 102b2 substantially functions as a wiring. As a result, the electrode 106 can be disposed at a position sufficiently away from the first region 102a corresponding to the light emitting region 103a (position sufficiently away from the optical waveguide).

The multilayer structure LS includes the substrate 100 disposed on the side opposite to the light emitting layer 103 side of the first semiconductor structure 101, and in the substrate 100, at least the surface layer on the first semiconductor structure 101 side has the low resistance region 100a having a lower resistance than the surrounding region. As a result, it is possible to form a conductive path having good conductivity, which is connected to the first semiconductor structure 101, on the substrate 100.

The low resistance region 100a has a higher impurity concentration than the surrounding region. As a result, the low resistance region 100a can be easily formed by impurity implantation (impurity diffusion).

The low resistance region 100a is provided around a region of the substrate 100 corresponding to the light emitting region 103a (region away from the optical waveguide). As a result, the low resistance region 100a and the light emitting region 103a can be electrically connected via the first semiconductor structure 101 while suppressing light absorption.

The multilayer structure LS has the another low resistance region 105 connected to the low resistance region 100a. As a result, it is possible to form a conductive path having good conductivity, which is connected to the low resistance region 100a, in the multilayer structure LS.

The another low resistance region 105 has a higher impurity concentration than the surrounding region. As a result, the another low resistance region 105 can be easily formed by impurity implantation (impurity diffusion).

The multilayer structure LS has the second mesa M2 in which the electrode 107 is installed on the top, and the another low resistance region 105 extends at least inside the second mesa M2 in the stacking direction, and has one end connected to the low resistance region 100a and the other end connected to the electrode 107. As a result, the electrode 107 placed on the top of the second mesa M2 and the low resistance region 100a can be electrically connected with good conductivity. Note that the mesa usually has a side surface that stands substantially vertically, and there is a problem that a wire is easily disconnected when the wire is routed along the mesa. However, since the surface emitting element 10 does not require a wire, such a problem does not occur.

The low resistance region 100a and the another low resistance region 105 are of the same conductivity type. As a result, the low resistance region 100a and the another low resistance region 105 can be used on the same side of the light emitting layer 103 with respect to the conduction direction.

The first and second regions 102a and 102b are of different conductivity types. As a result, a uniform electric field can be formed in the plane of the first region 102a, and a current can flow uniformly.

The first semiconductor structure 101 and the first region 102a are of the same conductivity type. As a result, a uniform electric field can be formed in the plane of the first region 102a, and a current can flow uniformly.

At least one of the first and second semiconductor structures 101 and 102 may include a reflecting mirror. In this case, the surface emitting element 10 can be used as a high-output light emitting diode or a surface emitting laser.

### Example 1

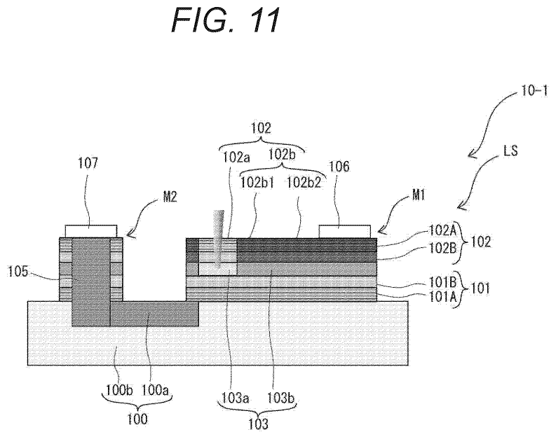

Hereinafter, a surface emitting element 10-1 according to Example 1 of the first embodiment will be described with reference to FIG. 11. As illustrated in FIG. 11, the surface emitting element 10-1 is a surface emitting laser in which both first and second semiconductor structures 101 and 102 have a reflecting mirror.

In the surface emitting element 10-1, the first semiconductor structure 101 includes a first reflecting mirror 101A and a first cladding layer 101B stacked on each other. The first cladding layer 101B is disposed between a light emitting layer 103 and the first reflecting mirror 101A.

In the surface emitting element 10-1, the second semiconductor structure 101 includes a second reflecting mirror 102A and a second cladding layer 102B stacked on each other. The second cladding layer 102B is disposed between a light emitting layer 103 and the second reflecting mirror 102A.

### Reflecting Mirror

As an example, each of the first and second reflecting mirrors 101A and 102A is a semiconductor multilayer film reflecting mirror doped with impurities, has little light absorption, and has high reflectance and conductivity. The semiconductor multilayer film reflecting mirror has a structure in which a plurality of types (for example, two types) of semiconductor layers having different refractive indexes is alternately stacked with an optical thickness of ¼ wavelength of emission wavelength. As an example, the first reflecting mirror 101A of each of the first and second mesas M1 and M2 is a semiconductor multilayer film reflecting mirror of a first conductivity type. The second reflecting mirror 102A in the second region 102b of the second semiconductor structure 102 of the first mesa M1 is a semiconductor multilayer film reflecting mirror of a second conductivity type, and the second reflecting mirror 102A in the first region 102a is a semiconductor multilayer film reflecting mirror of the first conductivity type. The reflectance of the first reflecting mirror 101A is set slightly higher than that of the second reflecting mirror 102A. That is, the surface emitting element 10-1 is a surface emission type surface emitting laser that emits light to the surface side.

Note that each of the first and second reflecting mirrors 101A and 102A may be, for example, a dielectric multilayer film reflecting mirror, a hybrid mirror including a dielectric multilayer film reflecting mirror and a semiconductor multilayer film reflecting mirror, a hybrid mirror including a semiconductor multilayer film reflecting mirror and a metal reflecting mirror, or a hybrid mirror including a dielectric multilayer film reflecting mirror and a metal reflecting mirror. The first and second reflecting mirrors 101A and 102A may be different types of reflecting mirrors.

### Cladding Layer

The first cladding layer 101B is a compound semiconductor of the first conductivity type. The second cladding layer 102B includes a compound semiconductor of the second conductivity type. Each cladding layer is also referred to as a spacer layer.

According to the surface emitting element 10-1, it is possible to realize a surface emission type high-output surface emitting laser suitable for mounting in a junction-up manner.

### Example 2

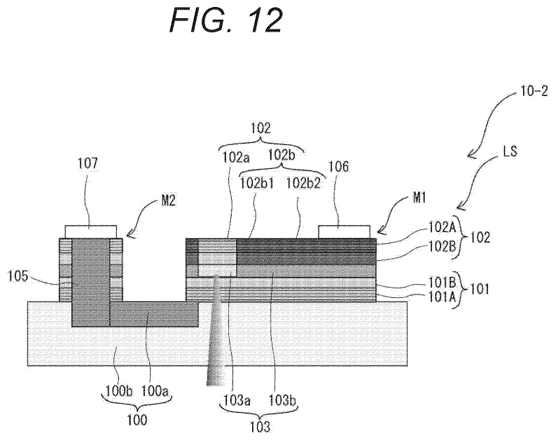

Hereinafter, a surface emitting element 10-2 according to Example 2 of the first embodiment will be described with reference to FIG. 12. As illustrated in FIG. 12, the surface emitting element 10-2 has a configuration similar to the surface emitting element 10-1 according to Example 1 except that it is a back surface emission type surface emitting laser that emits light to the back surface side. In the surface emitting element 10-2, the reflectance of the first reflecting mirror 101A is set to be slightly lower than that of the second reflecting mirror 102A.

According to the surface emitting element 10-2, it is possible to realize a back surface emission type high-output surface emitting laser suitable for mounting in a junction-down manner.

### Example 3

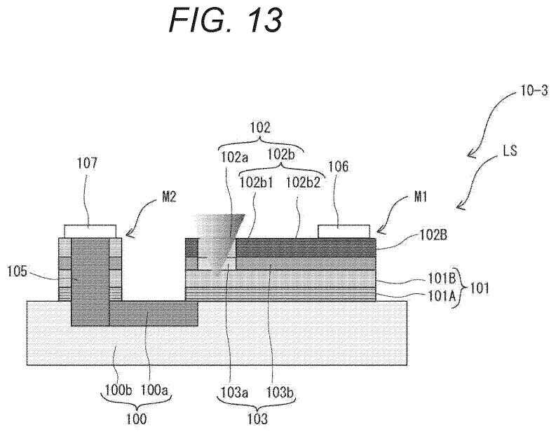

Hereinafter, a surface emitting element 10-3 according to Example 3 of the first embodiment will be described with reference to FIG. 13. As illustrated in FIG. 13, the surface emitting element 10-3 has a configuration similar to the surface emitting element 10-1 according to Example 1 except that the first semiconductor structure 101 is a light emitting diode (LED) having the first reflecting mirror 101A.

According to the surface emitting element 10-3, it is possible to realize a surface emission type high-output light emitting diode suitable for mounting in a junction-up manner.

### Example 4

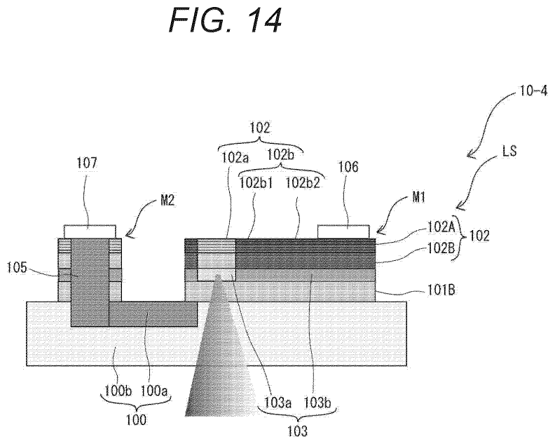

Hereinafter, a surface emitting element 10-4 according to Example 4 of the first embodiment will be described with reference to FIG. 14. As illustrated in FIG. 14, the surface emitting element 10-4 has a configuration similar to the surface emitting element 10-1 according to Example 1 except that a second semiconductor structure 102 is a light emitting diode (LED) having a second reflecting mirror 102A.

According to the surface emitting element 10-4, it is possible to realize a back surface emission type high-output light emitting diode suitable for mounting in a junction-down manner.

### 2. Surface Emitting Element According to Second Embodiment of Present Technology

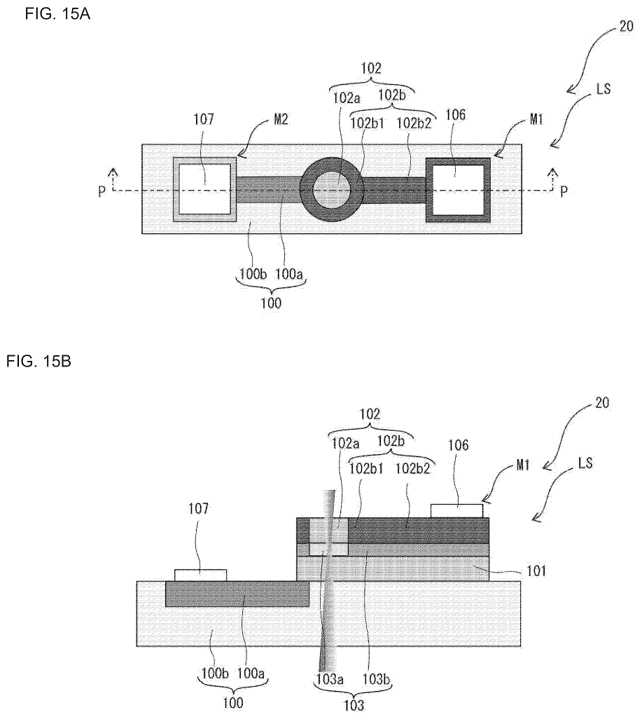

FIG. 15 is a plan view of a surface emitting element 20 according to a second embodiment of the present technology. FIG. 15A is a cross-sectional view of the surface emitting element 20 according to the second embodiment of the present technology. FIG. 15B is a cross-sectional view taken along line P-P in FIG. 15A. Hereinafter, in the cross-sectional view of FIG. 15B and the like, an upper side will be described as “upper” and a lower side will be described as “lower” as appropriate.

The surface emitting element 20 has a configuration similar to the surface emitting element 10 according to the first embodiment except that an electrode 107 is provided on a low resistance region 100a.

The surface emitting element 20 does not have a second mesa M2, and the electrode 107 is directly installed on the low resistance region 100a.

The surface emitting element 20 can be manufactured by a manufacturing method according to the method for manufacturing the surface emitting element 10 according to the first embodiment.

According to the surface emitting element 20, although electrodes 106 and 107 cannot be arranged at substantially the same height, since the second mesa M2 and the another low resistance region 105 are not formed, the manufacturing process can be simplified, and the manufacturing cost can be reduced.

### Example 1

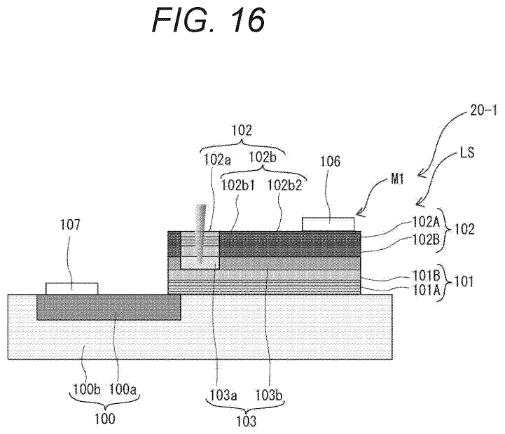

Hereinafter, a surface emitting element 20-1 according to Example 1 of the second embodiment will be described with reference to FIG. 16. As illustrated in FIG. 16, the surface emitting element 20-1 is a surface emitting laser in which both first and second semiconductor structures 101 and 102 have a reflecting mirror.

In the surface emitting element 20-1, the first semiconductor structure 101 includes a first reflecting mirror 101A and a first cladding layer 101B stacked on each other. The first cladding layer 101B is disposed between a light emitting layer 103 and the first reflecting mirror 101A.

In the surface emitting element 20-1, the second semiconductor structure 101 includes a second reflecting mirror 102A and a second cladding layer 102B stacked on each other. The second cladding layer 102B is disposed between a light emitting layer 103 and the second reflecting mirror 102A.

According to the surface emitting element 20-1, it is possible to realize a surface emission type surface emitting laser of a high output and low cost.

### Example 2

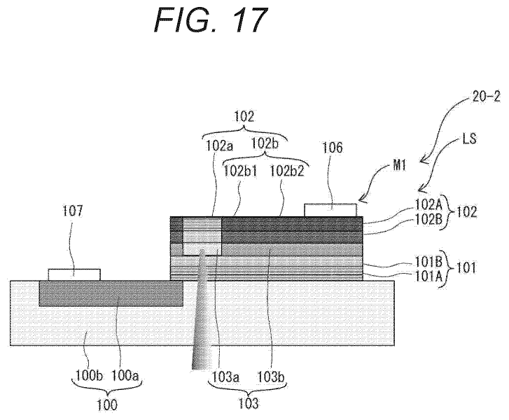

Hereinafter, a surface emitting element 20-2 according to Example 2 of the second embodiment will be described with reference to FIG. 17. As illustrated in FIG. 17, the surface emitting element 20-2 has a configuration similar to that of the surface emitting element 20-1 according to Example 1 except that the surface emitting element 20-2 is a back surface emission type surface emitting laser that emits light to the back surface side as illustrated in FIG. 17. In the surface emitting element 20-2, the reflectance of the first reflecting mirror 101A is set to be slightly lower than that of the second reflecting mirror 102A.

According to the surface emitting element 20-2, it is possible to realize a back surface emission type surface emitting laser of a high output and low cost.

### Example 3

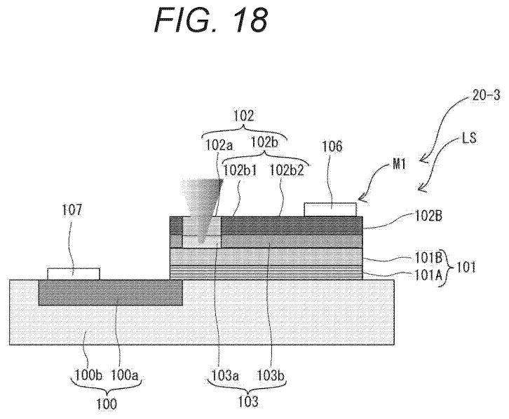

Hereinafter, a surface emitting element 20-3 according to Example 3 of the second embodiment will be described with reference to FIG. 18. As illustrated in FIG. 18, the surface emitting element 20-3 has a configuration similar to the surface emitting element 20-1 according to Example 1 except that a first semiconductor structure 101 is a light emitting diode (LED) having a first reflecting mirror 101A.

According to the surface emitting element 20-3, it is possible to realize a surface emission type high-output light emitting diode of a high output and low cost.

### Example 4

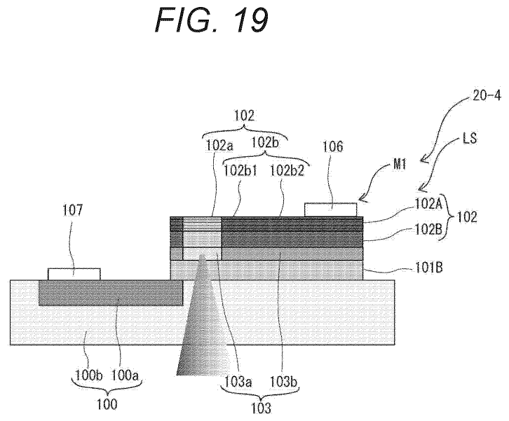

Hereinafter, a surface emitting element 20-4 according to Example 4 of the second embodiment will be described with reference to FIG. 19. As illustrated in FIG. 19, the surface emitting element 20-4 has a configuration similar to the surface emitting element 20-1 according to Example 1 except that a second semiconductor structure 102 is a light emitting diode (LED) having a second reflecting mirror 102A.

According to the surface emitting element 20-4, it is possible to realize a back surface emission type laser high-output light emitting diode of a high output and low cost.

### 3. Surface Emitting Element According to Third Embodiment of Present Technology

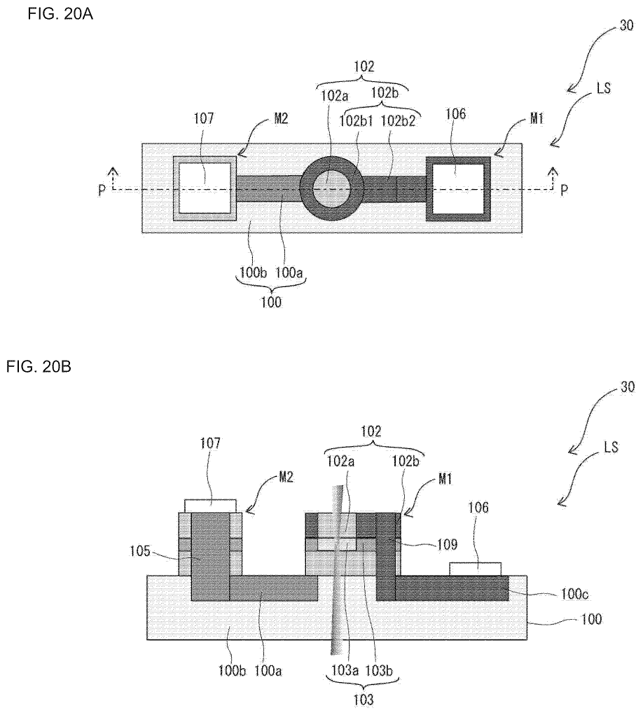

FIG. 20 is a plan view of a surface emitting element 30 according to a third embodiment of the present technology. FIG. 20A is a cross-sectional view of the surface emitting element 30 according to the third embodiment of the present technology. FIG. 20B is a cross-sectional view taken along line P-P in FIG. 20 A. Hereinafter, in the cross-sectional view of FIG. 20B and the like, an upper side will be described as “upper” and a lower side will be described as “lower” as appropriate.

The surface emitting element 30 has a configuration substantially similar to the surface emitting element 10 according to the first embodiment except that an electrode 106 is not provided on a first mesa M1.

In the surface emitting element 30, a low resistance region 100c of a second conductivity type is provided on at least a surface layer on a first semiconductor structure 101 side of a substrate 100. The electrode 106 is disposed on the low resistance region 100c.

In the surface emitting element 30, still another low resistance region 109 extending in the stacking direction inside the first mesa M1 and having one end (upper end) connected to a second region 102b and the other end (lower end) connected to the low resistance region 100c is provided.

In the surface emitting element 30, the first mesa M1 is smaller than the surface emitting element 10. The still another low resistance region 109 is a highly doped region of the second conductivity type having an impurity concentration higher than that of a surrounding region of the still another low resistance region 109 in the first mesa M1.

The surface emitting element 30 can be manufactured by a manufacturing method according to the method for manufacturing the surface emitting element 10 according to the first embodiment.

According to the surface emitting element 30, the similar effects as those of the surface emitting element 10 according to the first embodiment can be obtained except that the electrodes 106 and 107 cannot be arranged at substantially the same height.

### Example 1

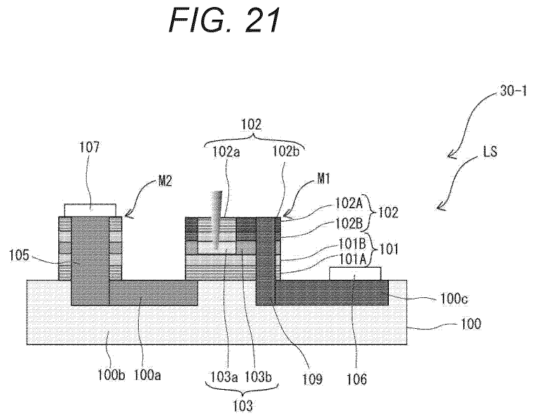

Hereinafter, a surface emitting element 30-1 according to Example 1 of the third embodiment will be described with reference to FIG. 21. As illustrated in FIG. 21, the surface emitting element 30-1 is a surface emitting laser in which both first and second semiconductor structures 101 and 102 have a reflecting mirror.

In the surface emitting element 30-1, the first semiconductor structure 101 includes a first reflecting mirror 101A and a first cladding layer 101B stacked on each other. The first cladding layer 101B is disposed between a light emitting layer 103 and the first reflecting mirror 101A.

In the surface emitting element 30-1, the second semiconductor structure 101 includes a second reflecting mirror 102A and a second cladding layer 102B stacked on each other. The second cladding layer 102B is disposed between a light emitting layer 103 and the second reflecting mirror 102A.

According to the surface emitting element 30-1, a surface emission type high-output surface emitting laser can be realized.

### Example 2

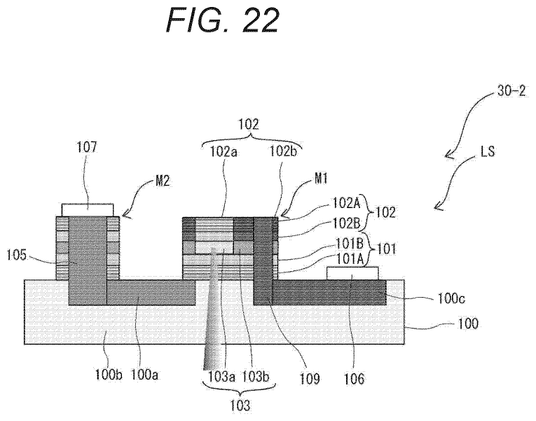

Hereinafter, a surface emitting element 30-2 according to Example 2 of the third embodiment will be described with reference to FIG. 22. As illustrated in FIG. 22, the surface emitting element 30-2 has a configuration similar to the surface emitting element 30-1 according to Example 1 except that it is a back surface emission type surface emitting laser that emits light to the back surface side. In the surface emitting element 30-2, the reflectance of the first reflecting mirror 101A is set to be slightly lower than that of the second reflecting mirror 102A.

According to the surface emitting element 30-2, a back surface emission type high-output surface emitting laser can be realized.

### Example 3

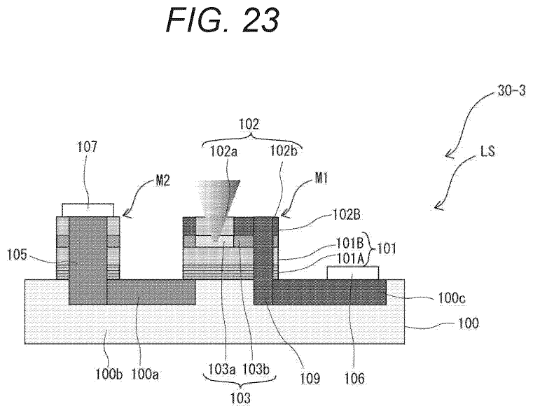

Hereinafter, a surface emitting element 30-3 according to Example 3 of the third embodiment will be described with reference to FIG. 23. As illustrated in FIG. 23, the surface emitting element 30-3 has a configuration similar to the surface emitting element 30-1 according to Example 1 except that a first semiconductor structure 101 is a light emitting diode (LED) having a first reflecting mirror 101A.

According to the surface emitting element 30-3, it is possible to realize a surface emission type high-output light emitting diode.

### Example 4

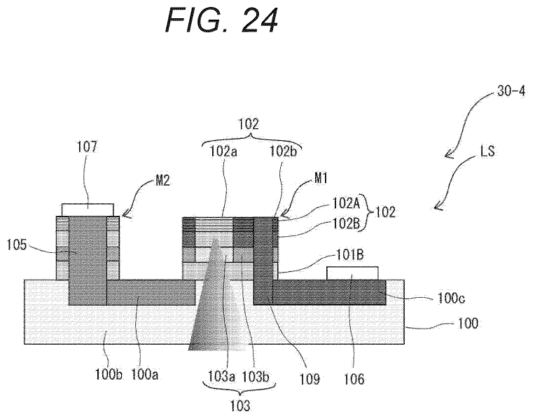

Hereinafter, a surface emitting element 30-4 according to Example 4 of the first embodiment will be described with reference to FIG. 24. As illustrated in FIG. 24, the surface emitting element 30-4 has a configuration similar to the surface emitting element 30-1 according to Example 1 except that a second semiconductor structure 102 is a light emitting diode (LED) having a second reflecting mirror 102A.

According to the surface emitting element 30-4, it is possible to realize a back surface emission type high-output light emitting diode.

### 4. Surface Emitting Element According to Fourth Embodiment of Present Technology

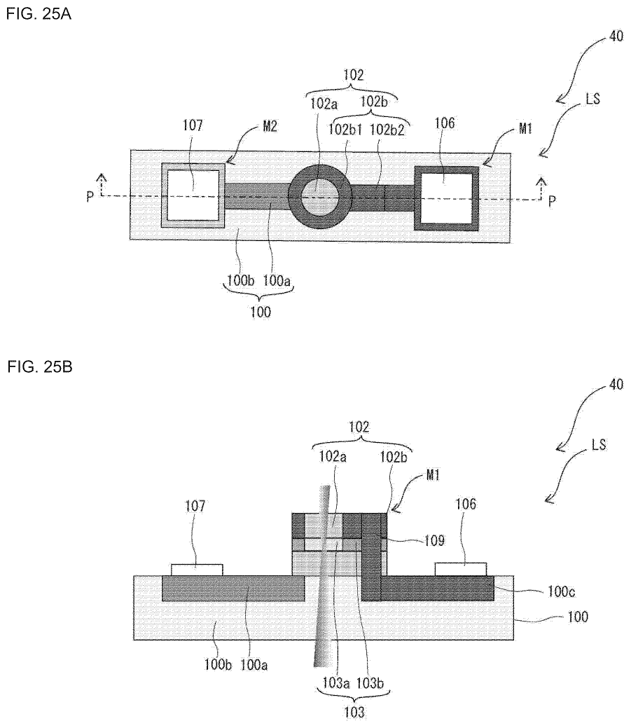

FIG. 25 is a plan view of a surface emitting element 40 according to a fourth embodiment of the present technology. FIG. 25A is a cross-sectional view of a surface emitting element 40 according to a fourth embodiment of the present technology. FIG. 25B is a cross-sectional view taken along line P-P in FIG. 25A. Hereinafter, in the cross-sectional view of FIG. 25B and the like, an upper side will be described as “upper” and a lower side will be described as “lower” as appropriate.

The surface emitting element 40 has a configuration substantially similar to the surface emitting element 10 according to the first embodiment except that an electrode 107 is provided on a low resistance region 100a and an electrode 106 is provided on a low resistance region 100c.

The surface emitting element 40 does not have a second mesa M2, and the electrode 107 is directly disposed on the low resistance region 100a and the electrode 106 is directly disposed on the low resistance region 100c.

The surface emitting element 40 can be manufactured by a manufacturing method according to the method for manufacturing the surface emitting element 10 according to the first embodiment.

According to the surface emitting element 40, the similar effect as that of the surface emitting element 10 according to the first embodiment can be obtained.

### Example 1

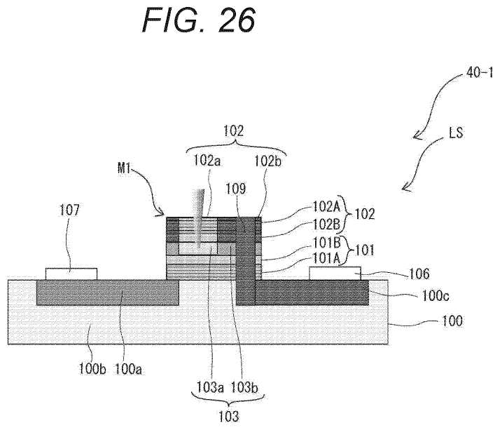

Hereinafter, a surface emitting element 40-1 according to Example 1 of the fourth embodiment will be described with reference to FIG. 26. As illustrated in FIG. 26, the surface emitting element 40-1 is a surface emitting laser in which both first and second semiconductor structures 101 and 102 have a reflecting mirror.

In the surface emitting element 40-1, the first semiconductor structure 101 includes a first reflecting mirror 101A and a first cladding layer 101B stacked on each other. The first cladding layer 101B is disposed between a light emitting layer 103 and the first reflecting mirror 101A.

In the surface emitting element 40-1, the second semiconductor structure 101 includes a second reflecting mirror 102A and a second cladding layer 102B stacked on each other. The second cladding layer 102B is disposed between a light emitting layer 103 and the second reflecting mirror 102A.

According to the surface emitting element 40-1, a surface emission type high-output surface emitting laser can be realized.

### Example 2

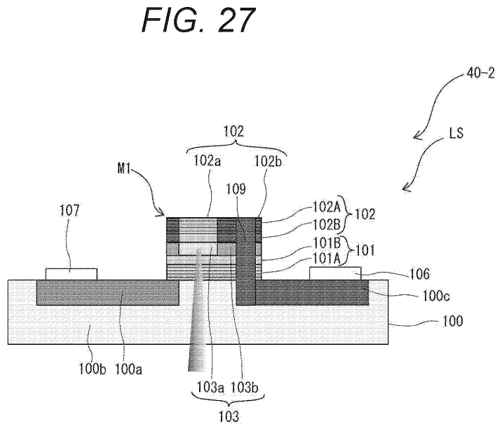

Hereinafter, a surface emitting element 40-2 according to Example 2 of the fourth embodiment will be described with reference to FIG. 27. As illustrated in FIG. 27, the surface emitting element 40-2 has a configuration similar to the surface emitting element 40-1 according to Example 1 except that it is a back surface emission type surface emitting laser that emits light to the back surface side. In the surface emitting element 40-2, the reflectance of a first reflecting mirror 101A is set to be slightly lower than that of a second reflecting mirror 102A.

According to the surface emitting element 40-2, a back surface emission type high-output surface emitting laser can be realized.

### Example 3

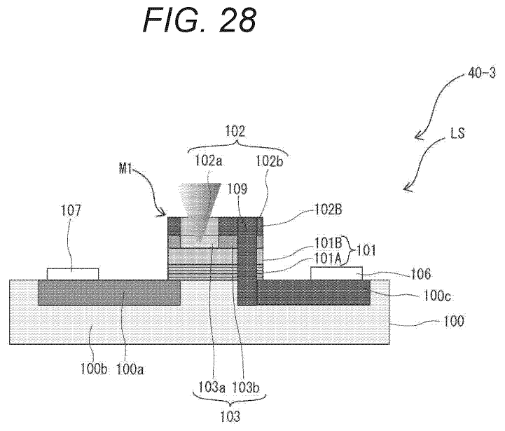

Hereinafter, a surface emitting element 40-3 according to Example 3 of the fourth embodiment will be described with reference to FIG. 28. As illustrated in FIG. 28, the surface emitting element 40-3 has a configuration similar to the surface emitting element 40-1 according to Example 1 except that a first semiconductor structure 101 is a light emitting diode (LED) having a first reflecting mirror 101A.

According to the surface emitting element 40-3, it is possible to realize a surface emission type high-output light emitting diode.

### Example 4

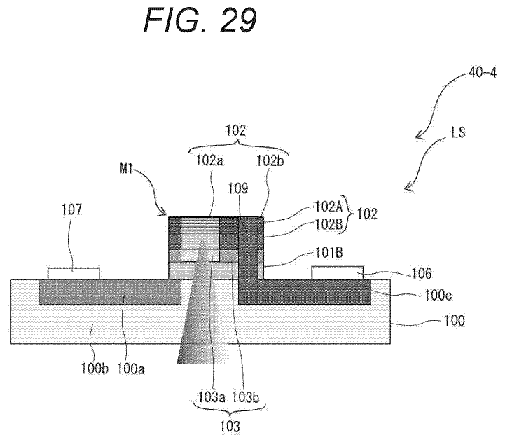

Hereinafter, a surface emitting element 40-4 according to Example 4 of the fourth embodiment will be described with reference to FIG. 29. As illustrated in FIG. 29, the surface emitting element 40-4 has a configuration similar to the surface emitting element 40-1 according to Example 1 except that a second semiconductor structure 102 is a light emitting diode (LED) having a second reflecting mirror 102A.

According to the surface emitting element 40-4, it is possible to realize a back surface emission type high-output light emitting diode.

### 5. Surface Emitting Element According to Fifth Embodiment of Present Technology

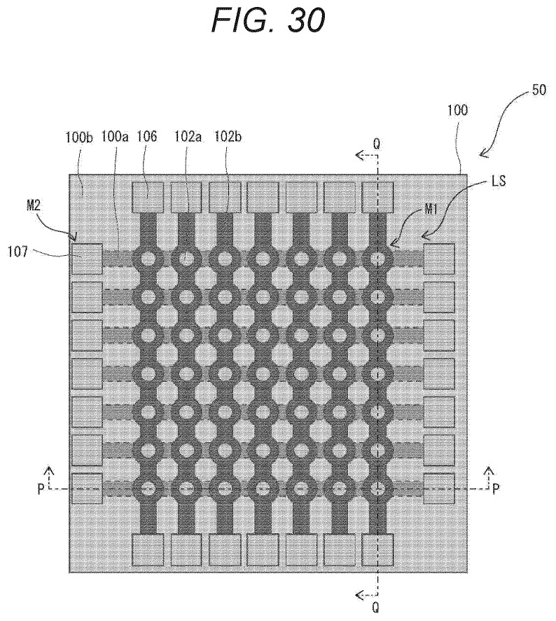

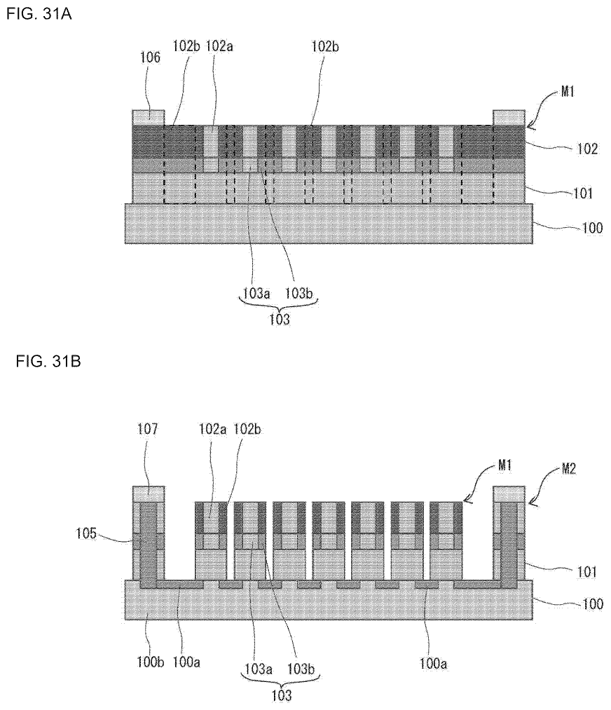

FIG. 30 is a plan view of a surface emitting element 50 according to a fifth embodiment of the present technology. FIG. 31A is a cross-sectional view (part 1) of the surface emitting element 50 according to the fifth embodiment of the present technology. FIG. 31B is a cross-sectional view (part 2) of the surface emitting element 50 according to the fifth embodiment of the present technology. FIG. 31A is a cross-sectional view taken along line Q-Q in FIG. 30, and FIG. 31B is a cross-sectional view taken along line P-P in FIG. 30. Hereinafter, in the cross-sectional views of FIGS. 31A and 31B, an upper side will be described as “upper” and a lower side will be described as “lower” as appropriate.

In the surface emitting element 50, when two directions intersecting (for example, orthogonal to) each other in a plane orthogonal to the stacking direction are a first direction (for example, the Q-Q line direction) and a second direction (for example, the P-P line direction), a substrate 100 has a plurality of (for example, seven) low resistance regions 100a each extending along the first direction and aligned along the second direction, and a second semiconductor structure 102 has a plurality of (for example, seven) second regions 102b each extending along the second direction and aligned along the first direction.

In the surface emitting element 50, a light emitting region 103a is located at an intersection of each low resistance region 100a and each second region 102b in plan view (as viewed from the stacking direction). The electrodes 106 are connected to both ends of each of the second regions 102b. The electrodes 107 are connected to both ends of each low resistance region 100a.

That is, the surface emitting element 50 has a current injection structure of passive matrix arrangement, and can independently drive each light emitting region 103a.

In the surface emitting element 50, at least one of the plurality of second regions 102b and at least one of the plurality of low resistance regions 100a are selected and energized, so that at least one arbitrary (desired) light emitting region 103a can emit light.

According to the surface emitting element 50, it is possible to realize a light emitting unit array in which a plurality of high-output light emitting units is arranged in an ultra-high density array (for example, in a matrix). Furthermore, since wiring is unnecessary, a significant cost reduction can be expected.

### 6. Modification of Present Technology

### Surface Emitting Element According to Modification 1 of First Embodiment of Present Technology

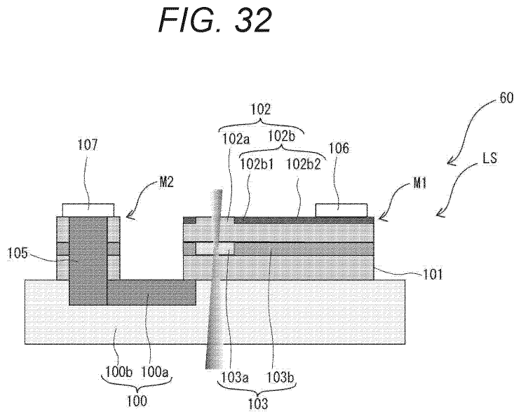

FIG. 32 is a cross-sectional view of a surface emitting element 60 according to Modification 1 of the first embodiment of the present technology. The surface emitting element 60 has a configuration similar to the surface emitting element 10 according to the first embodiment except that first and second regions 102a and 102b are provided only on a surface layer on a side opposite to a light emitting layer 103 side of a second semiconductor structure 102.

### Surface Emitting Element According to Modification 2 of First Embodiment of Present Technology

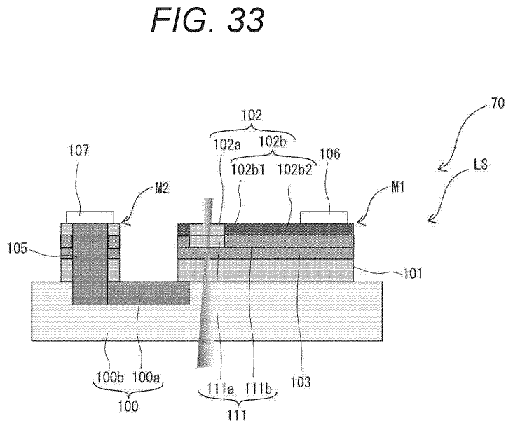

FIG. 33 is a cross-sectional view of a surface emitting element 70 according to Modification 2 of the first embodiment of the present technology. The surface emitting element 70 has a configuration substantially similar to the surface emitting element 10 according to the first embodiment except that a second semiconductor structure 102 has an oxidation confinement layer 111 (current confinement layer) as an intermediate layer between a surface layer which is a highly doped region and a light emitting layer 103.

The oxidation confinement layer 111 has a non-oxidized region 111a and an oxidized region 111b (current confinement region) surrounding the non-oxidized region 111a. As an example, the non-oxidized region 111a includes a compound semiconductor (for example, a compound semiconductor containing Al) of the first conductivity type. As an example, the non-oxidized region 111a is substantially the same in shape and size as the first region 102a. As an example, the oxidized region 111b includes an insulator such as a metal oxide containing Al.

### Surface Emitting Element According to Modification 3 of First Embodiment of Present Technology

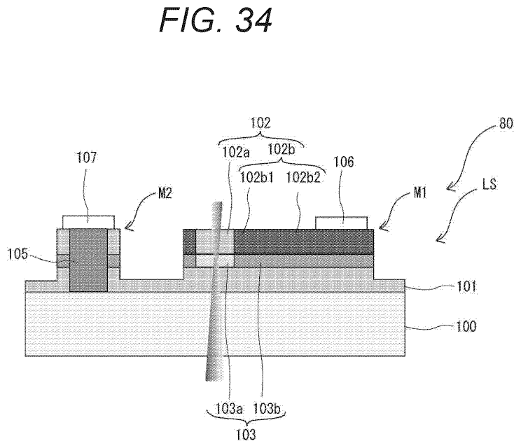

FIG. 34 is a cross-sectional view of a surface emitting element 80 according to Modification 3 of the first embodiment of the present technology. The surface emitting element 80 has a configuration similar to the surface emitting element 10 according to the first embodiment except that bottom surfaces of first and second mesas M1 and M2 are located in a first semiconductor structure 101 and a low resistance region 100a is not provided.

In the surface emitting element 80, the first semiconductor structure 101 extends over the first and second mesas M1 and M2. As a result, a conduction path (current path) for electrically connecting the first and second mesas M1 and M2 is formed in the first semiconductor structure 101. In the surface emitting element 80, another low resistance region 105 is provided only in the second mesa M2.

### Surface Emitting Element According to Modification 4 of First Embodiment of Present Technology

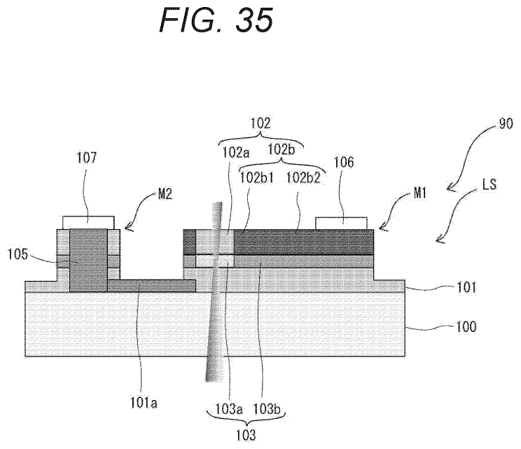

FIG. 35 is a cross-sectional view of a surface emitting element 90 according to Modification 4 of the first embodiment of the present technology. The surface emitting element 90 has a configuration similar to the surface emitting element 80 according to Modification 3 except that a low resistance region 101a is provided in one semiconductor structure 101.

### Surface Emitting Element According to Modification 5 of First Embodiment of Present Technology

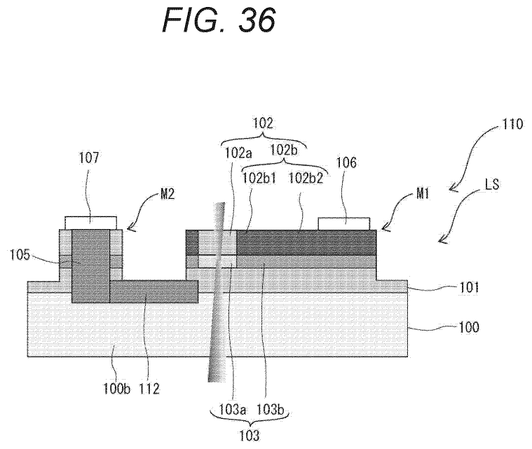

FIG. 36 is a cross-sectional view of a surface emitting element 110 according to Modification 5 of the first embodiment of the present technology. The surface emitting element 110 has a configuration similar to the surface emitting element 90 according to Modification 4 except that each of a low resistance region 112 and another low resistance region 105 is provided across a substrate 100 and a first semiconductor structure 102.

### Surface Emitting Element According to Modification 1 of Second Embodiment of Present Technology

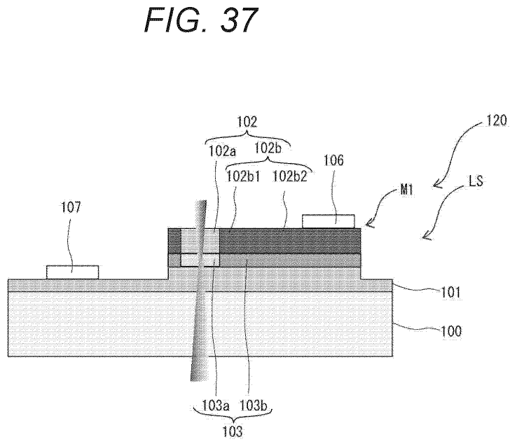

FIG. 37 is a cross-sectional view of a surface emitting element 120 according to Modification 1 of the second embodiment of the present technology. The surface emitting element 120 has a configuration similar to the surface emitting element 20 according to the second embodiment except that a bottom surface of a first mesa M1 is located in a first semiconductor structure 101 and a low resistance region 100a is not provided.

In the surface emitting element 120, an electrode 107 is installed on a portion outside the first mesa M1 of the first semiconductor structure 101.

### Surface Emitting Element According to Modification 2 of Second Embodiment of Present Technology

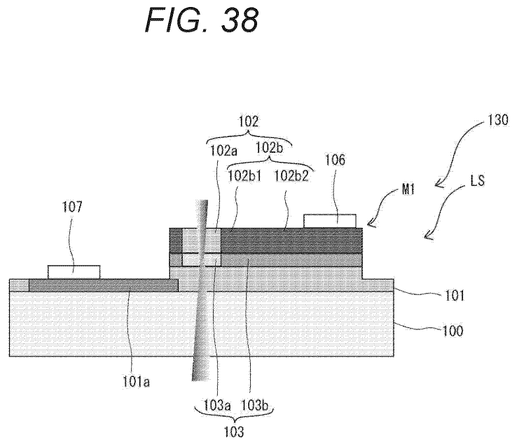

FIG. 38 is a cross-sectional view of a surface emitting element 130 according to Modification 1 of the second embodiment of the present technology. The surface emitting element 130 has a configuration similar to the surface emitting element 120 according to Modification 1 except that a low resistance region 101a is provided in a first semiconductor structure 101.

### Surface emitting element according to Modification 3 of second embodiment of present technology

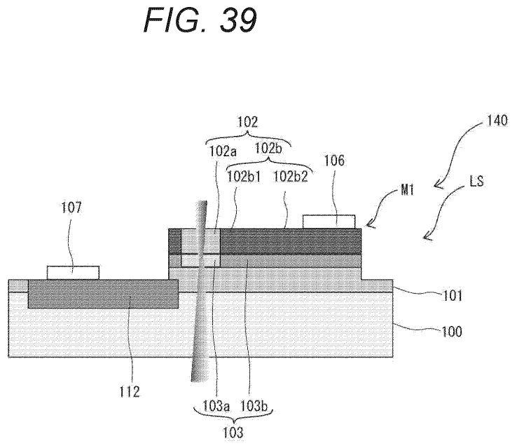

FIG. 39 is a cross-sectional view of a surface emitting element 140 according to Modification 3 of the second embodiment of the present technology. The surface emitting element 140 has a configuration similar to the surface emitting element 130 according to Modification 2 except that a low resistance region 112 is provided across a substrate 100 and a first semiconductor structure 101.

### Surface Emitting Element According to Modification 1 of Third Embodiment of Present Technology

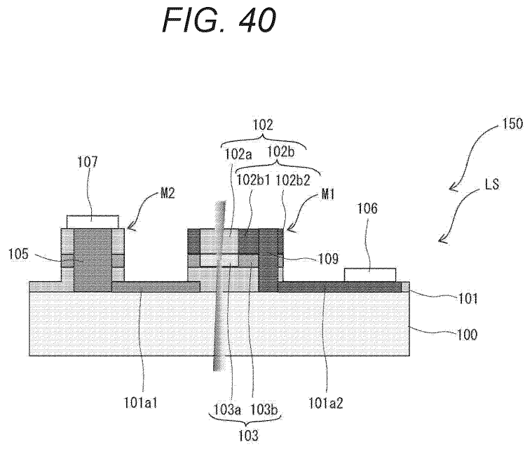

FIG. 40 is a cross-sectional view of a surface emitting element 150 according to Modification 1 of the third embodiment of the present technology. The surface emitting element 150 has a configuration substantially similar to the surface emitting element 20 according to the second embodiment except that bottom surfaces of first and second mesas M1 and M2 are located in a first semiconductor structure 101.

In the surface emitting element 150, a first low resistance region 101a1 connected to the another low resistance region 105 and a second low resistance region 101a2 connected to the still another low resistance region 109 are provided in the first semiconductor structure 101. An electrode 106 is disposed on the second low resistance region 101a2.

### Surface Emitting Element According to Modification 2 of Third Embodiment of Present Technology

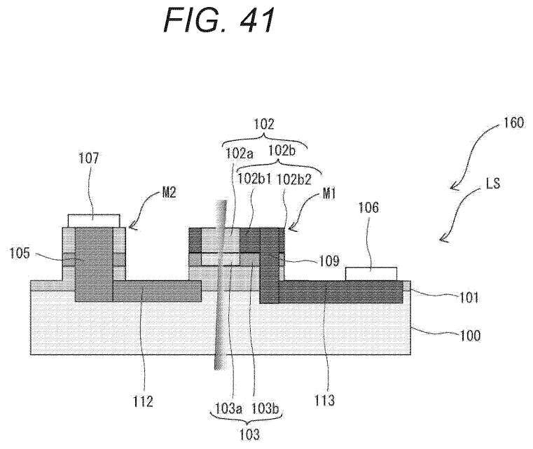

FIG. 41 is a cross-sectional view of a surface emitting element 160 according to Modification 2 of the third embodiment of the present technology. The surface emitting element 160 has a configuration similar to the surface emitting element 150 according to Modification 1 except that each of a low resistance region 112 connected to the another low resistance region 105 and a low resistance region 113 connected to the still another low resistance region 109 is provided across a substrate 100 and a first semiconductor structure 101.

### Surface Emitting Element According to Modification 1 of Fourth Embodiment of Present Technology

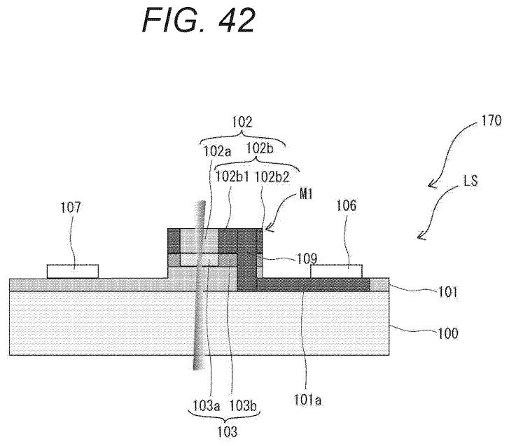

FIG. 42 is a cross-sectional view of a surface emitting element 170 according to Modification 1 of the fourth embodiment of the present technology. The surface emitting element 170 has a configuration substantially similar to the surface emitting element 40 according to the fourth embodiment except that bottom surfaces of first and second mesas M1 and M2 are located in a first semiconductor structure 101 and a low resistance region 100a is not provided.

In the surface emitting element 170, a low resistance region 101a connected to the still another low resistance region 109 is provided in the first semiconductor structure 101. An electrode 106 is disposed on a second low resistance region 101a2.

### Surface Emitting Element According to Modification 2 of Fourth Embodiment of Present Technology

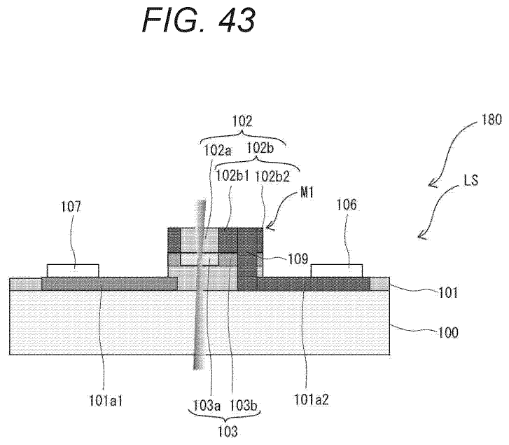

FIG. 43 is a cross-sectional view of a surface emitting element 180 according to Modification 2 of the fourth embodiment of the present technology. The surface emitting element 180 has a configuration similar to the surface emitting element 170 according to Modification 1 except that a first low resistance region 101a1 where an electrode 107 is disposed and a second low resistance region 101a2 connected to the still another low resistance region 109 where an electrode 106 is disposed are provided in a first semiconductor structure 101.

### Surface Emitting Element According to Modification 3 of Fourth Embodiment of Present Technology

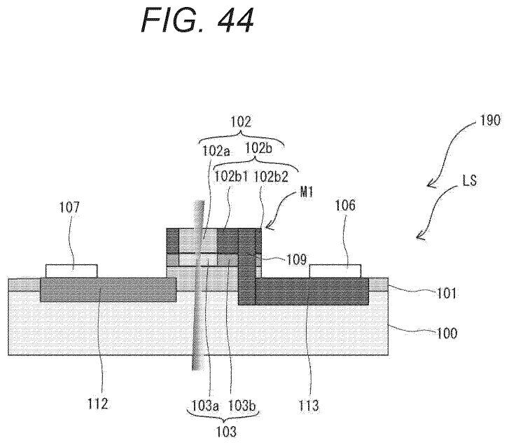

FIG. 44 is a cross-sectional view of a surface emitting element 190 according to Modification 3 of the fourth embodiment of the present technology. The surface emitting element 190 has a configuration similar to the surface emitting element 180 according to Modification 2 except that each of a low resistance region 112 where an electrode 107 is disposed and a low resistance region 113 connected to the still another low resistance region 109 where an electrode 106 is disposed is provided across a substrate 100 and a first semiconductor structure 101.

### Surface Emitting Element According to Modification of Present Technology

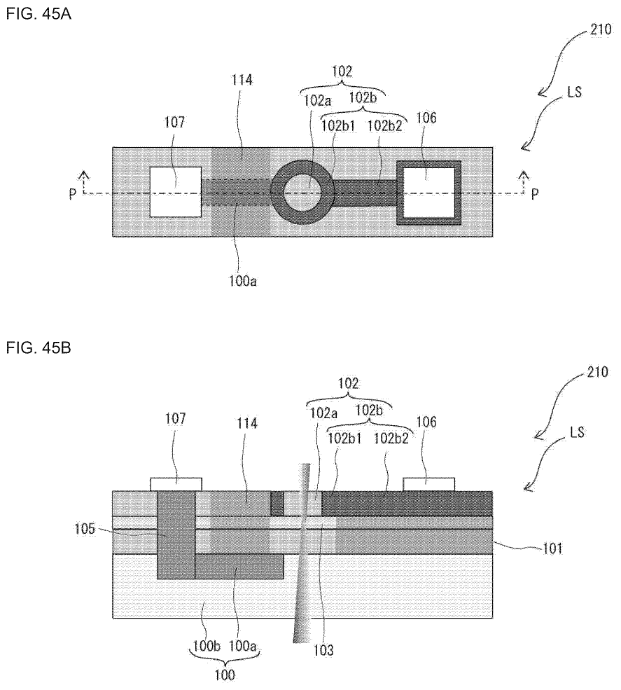

FIG. 45 is a cross-sectional view of a surface emitting element 210 according to a modification of the present technology. The surface emitting element 210 has a configuration substantially similar to the surface emitting element 10 according to the first embodiment except that it does not have a mesa.

In the surface emitting element 210, an ion implantation region 114 as a current confinement region for setting a light emitting region of a light emitting layer 103 is provided in a multilayer structure LS. The ion implanted region 114 is provided in a loop in first and second semiconductor structures 101 and 102, a region between another low resistance region 105 and a region (optical waveguide) corresponding to a first region 102a of the light emitting layer 103, and a region between an extending portion 102b2 of a second region 102b and a substrate 100. Examples of the ion species of the ion implantation region 114 include H⁺ and B⁺.

An example of a method for manufacturing the surface emitting element 210 will be briefly described. Impurity diffusion is performed on the substrate 100 to form a low resistance region 100a. The second semiconductor structure 102, the light emitting layer 103, and the first semiconductor structure 101 are stacked in this order on another substrate to form a multilayer structure. Impurity diffusion is performed from the second semiconductor structure 102 side of the multilayer structure to form the second region 102b. The ion implantation region 114 is formed by performing ion implantation from the first semiconductor structure 101 side of the multilayer structure. A surface of the substrate 100 on the low resistance region 100a side and a surface of the multilayer structure on the first semiconductor structure 101 side are aligned and joined.

In the surface emitting element according to each embodiment, each example, and each modification of the present technology, the second region 102b may not have the circling portion 102b1.

The surface emitting element according to each embodiment, each example, and each modification of the present technology may not have the low resistance region 100a.

In the surface emitting element according to each embodiment, each embodiment, and each modification of the present technology, in a case where the surface emitting element has the low resistance region 100a, the low resistance region 100a may not be in contact with any mesa.

In the surface emitting element according to each embodiment, each example, and each modification of the present technology, the first region 102a of the second semiconductor structure 102 is of the first conductivity type, but may be of the second conductivity type. That is, in the second semiconductor structure 102, both the first and second regions 102a and 102b may be of the second conductivity type. In this case, in the method for manufacturing the surface emitting element, the substrate 100, the first semiconductor structure 101 of the first conductivity type, the active layer 103, and the second semiconductor structure 102 of the second conductivity type may be stacked in this order to form a multilayer structure.

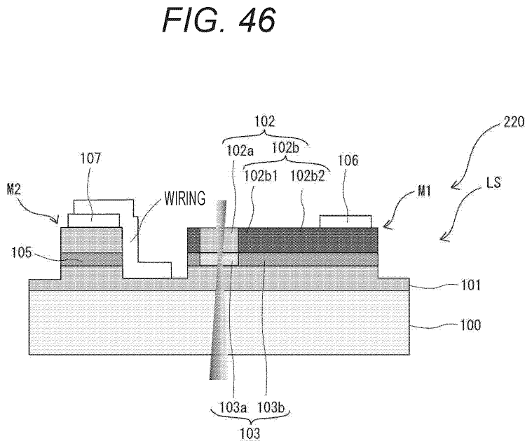

For example, as in the surface emitting element 220 according to the modification illustrated in FIG. 46, the first semiconductor structure 101 and the electrode 107 may be connected by wiring provided along the mesa M2.

A part of the configuration of the surface emitting element of each of the above embodiments, examples, and modifications may be combined within a range not contradictory to each other.

In each of the above embodiments, examples, and modifications, the material, conductivity type, thickness, width, numerical value, shape, size, and the like of each layer constituting the surface emitting element can be appropriately changed within a range functioning as the surface emitting element.

### 7. Application Example to Electronic Device

The technology according to the present disclosure (present technology) can be applied to various products (electronic devices). For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

The surface emitting element according to the present technology can also be applied as, for example, a light source of a device (for example, a printer, a copier, a projector, a head-mounted display, a head-up display, or the like) that forms or displays an image by light.

### 8. Example in Which Surface Emitting Element is Applied to Distance Measuring Device

Hereinafter, an application example of the surface emitting element 10 according to the first embodiment will be described.

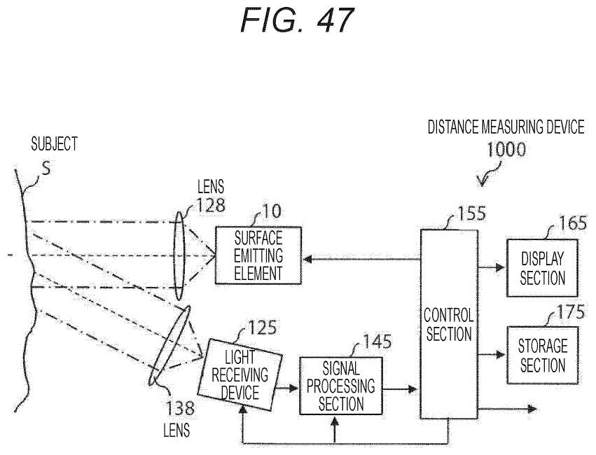

FIG. 47 illustrates an example of a schematic configuration of a distance measuring device 1000 (distance measurement device) including a surface emitting element 10 as an example of an electronic device according to the present technology. The distance measuring device 1000 measures a distance to a subject S by a time of flight (TOF) method. The distance measuring device 1000 includes the surface emitting element 10. The distance measuring device 1000 includes, for example, the surface emitting element 10, a light receiving device 125, lenses 128 and 138, a signal processing section 145, a control section 155, a display section 165, and a storage section 175.

The light receiving device 125 receives the light emitted from the surface emitting element 10 and reflected by the subject S (object). That is, the light receiving device 125 detects the light reflected by the subject S. The lens 128 is a lens for collimating the light emitted from the surface emitting element 10, and is, for example, a collimating lens. The lens 138 is a lens for collecting the light reflected by the subject S and guiding the light to the light receiving device 125, and is, for example, a condenser lens.

The signal processing section 145 is a circuit for generating a signal corresponding to a difference between the signal input from the light receiving device 125 and the reference signal input from the control section 155. The control section 155 includes, for example, a time to digital converter (TDC). The reference signal may be a signal input from the control section 155, or may be an output signal of a detecting section that directly detects the output of the surface emitting element 10. The control section 155 is, for example, a processor that controls the surface emitting element 10, the light receiving device 125, the signal processing section 145, the display section 165, and the storage section 175. The control section 155 is a circuit that measures the distance to the subject S on the basis of the signal generated by the signal processing section 145. The control section 155 generates a video signal for displaying information regarding the distance to the subject S, and outputs the video signal to the display section 165. The display section 165 displays the information regarding the distance to the subject S on the basis of the video signal input from the control section 155. The control section 155 stores the information regarding the distance to the subject S in the storage section 175.

In the present application example, in place of the surface emitting element 10, any one of the surface emitting elements 10-1 to 10-4, 20, 20-1 to 20-4, 30, 30-1 to 30-4, 40, 40-1 to 40-4, 50, 60, 70, 80, 90, 110, 120, 130, 140, 150, 160, 170, 180, 190, and 210 can be applied to the distance measuring device 1000.

### 9. Example in Which Distance Measurement Device is Mounted on Moving Body

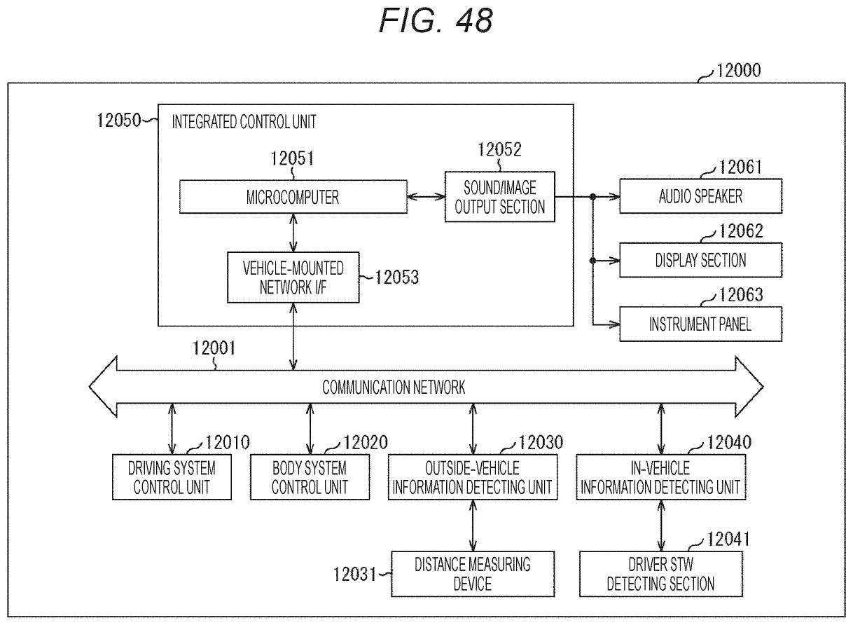

FIG. 48 is a block diagram illustrating a schematic configuration example of a vehicle control system which is an example of a mobile body control system to which the technology according to the present disclosure can be applied.

The vehicle control system 12000 includes a plurality of electronic control units connected to each other via a communication network 12001. In the example illustrated in FIG. 48, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the drive system of the vehicle in accordance with various programs. For example, the driving system control unit 12010 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back lamp, a brake lamp, a turn indicator, or a fog lamp. In this case, radio waves transmitted from a portable device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle including the vehicle control system 12000. For example, a distance measuring device 12031 is connected to the outside-vehicle information detecting unit 12030. The distance measuring device 12031 includes the distance measuring device 1000 described above. The outside-vehicle information detecting unit 12030 causes the distance measuring device 12031 to measure a distance to an object (subject S) outside the vehicle, and acquires distance data acquired by the measurement. The outside-vehicle information detecting unit 12030 may perform object detection processing of a person, a car, an obstacle, a sign, or the like on the basis of the acquired distance data.

The in-vehicle information detecting unit 12040 detects information regarding the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information regarding the inside or outside of the vehicle which is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle travel automatedly without depending on the operation of the driver, or the like, by controlling the driving force generating device, the steering mechanism, the braking device, or the like on the basis of the information regarding the surrounding of the vehicle which is obtained by the outside-vehicle information detecting unit 12030 or the in-vehicle information detecting unit 12040.

Furthermore, the microcomputer 12051 can output a control command to the body system control unit 12020 on the basis of the information regarding the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 48, an audio speaker 12061, a display section 12062, and an instrument panel 12063 are illustrated as output devices. The display section 12062 may, for example, include at least one of an on-board display and a head-up display.

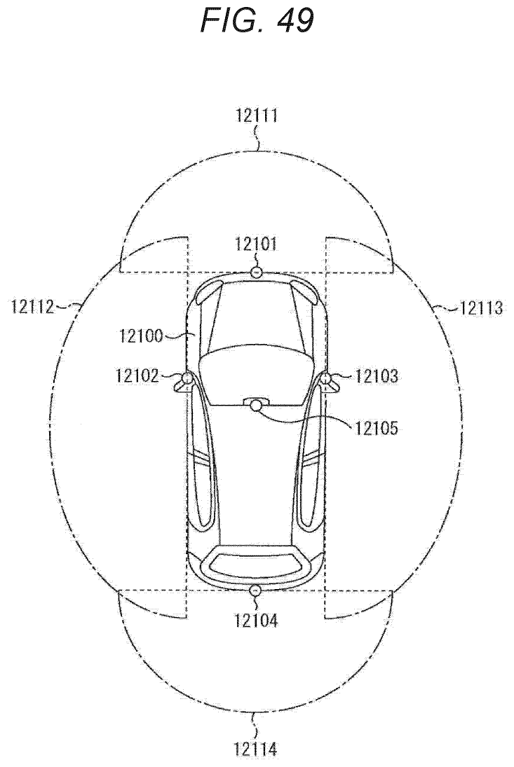

FIG. 49 is a view illustrating an example of an installation position of the distance measuring device 12031.

In FIG. 49, the vehicle 12100 includes distance measuring devices 12101, 12102, 12103, 12104, and 12105 as the distance measuring device 12031.

For example, the distance measuring devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measuring device 12101 provided at the front nose and the distance measuring device 12105 provided at the upper portion of the windshield in the vehicle interior mainly acquire data of the front side of the vehicle 12100. The distance measuring devices 12102 and 12103 provided at the sideview mirrors mainly acquire data of the sides of the vehicle 12100. The distance measuring device 12104 provided at the rear bumper or the back door mainly acquires data of the rear side of the vehicle 12100. The data of the front side acquired by the distance measuring devices 12101 and 12105 is mainly used to detect a preceding vehicle, a pedestrian, an obstacle, a traffic light, a traffic sign, or the like.

Note that FIG. 49 illustrates an example of detection ranges of the distance measuring devices 12101 to 12104. A detection range 12111 indicates a detection range of the distance measuring device 12101 provided at the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided at the rear bumper or the back door.

For example, the microcomputer 12051 obtains a distance to each three-dimensional object within the detection ranges 12111 to 12114 and a temporal change in the distance (relative speed with respect to the vehicle 12100) on the basis of the distance data obtained from the distance measuring devices 12101 to 12104, thereby extracting particularly a nearest three-dimensional object present on a traveling path of the vehicle 12100, which travels in substantially the same direction as the vehicle 12100 at a predetermined speed (for example, equal to or more than 0 km/h), as a preceding vehicle. Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data regarding three-dimensional objects into other three-dimensional objects such as two-wheeled vehicles, standard-sized vehicles, large-sized vehicles, pedestrians, and utility poles, extract the three-dimensional object data, and use the three-dimensional object data for automatic avoidance of obstacles, on the basis of the distance data obtained from the distance measuring devices 12101 to 12104. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

An example of the moving body control system to which the technology according to the present disclosure can be applied has been described above. The technology according to the present disclosure may be applied to the distance measuring device 12031 among the configurations described above.

Furthermore, the present technology may also adopt the following configurations.
(1) A surface emitting element including:
a multilayer structure including a first semiconductor structure and a second semiconductor structure stacked with each other, and
a light emitting layer disposed between the first semiconductor structure and the second semiconductor structure and having a light emitting region, in which
in the second semiconductor structure, at least a surface layer on a side opposite to the light emitting layer side has a first region corresponding to the light emitting region and a second region that is a surrounding region of the first region and has lower resistance than the first region.
(2) The surface emitting element according to (1), in which the multilayer structure is provided with a current confinement region for setting the light emitting region.
(3) The surface emitting element according to (1) or (2), in which the second region has a higher impurity concentration than the first region.
(4) The surface emitting element according to any one of (1) to (3), in which an electrode is provided on the second region.
(5) The surface emitting element according to any one of (1) to (4), in which the second region has an extending portion extending in an in-plane direction from the first region side, and the electrode is installed on the extending portion.
(6) The surface emitting element according to any one of (1) to (5), in which the second region has a circling portion surrounding the first region.
(7) The surface emitting element according to any one of (1) to (6), in which the multilayer structure includes a substrate disposed on a side opposite to the light emitting layer side of the first semiconductor structure, and at least a surface layer of the substrate on the first semiconductor structure side and/or at least a surface layer of the first semiconductor structure on the substrate side have a low resistance region.
(8) The surface emitting element according to (7), in which the low resistance region has a higher impurity concentration than a surrounding region thereof.
(9) The surface emitting element according to (7) or (8), in which the low resistance region is provided in a surrounding region of the substrate and/or the first semiconductor structure corresponding to the light emitting region.
(10) The surface emitting element according to any one of (7) to (9), in which an electrode is provided on the low resistance region.
(11) The surface emitting element according to any one of (7) to (10), in which the multilayer structure has another low resistance region connected to the low resistance region.
(12) The surface emitting element according to (11), in which the another low resistance region has a higher impurity concentration than a surrounding region thereof.
(13) The surface emitting element according to (11) or (12), in which the multilayer structure has a mesa on the substrate, the mesa having an electrode placed on a top, and the another low resistance region extends at least inside the second mesa in a stacking direction, and has one end connected to the low resistance region and the other end connected to the electrode.
(14) The surface emitting element according to (11) or (12), in which the multilayer structure has a mesa including the light emitting region on the substrate, and the another low resistance region extends inside the mesa in a stacking direction, and has one end connected to the second region and the other end connected to the low resistance region.
(15) The surface emitting element according to any one of (11) to (14), in which the low resistance region and the another low resistance region are of the same conductivity type.
(16) The surface emitting element according to (1) to (15), in which the first region and the second region are of different conductivity types.
(17) The surface emitting element according to any one of (1) to (16), in which the first semiconductor structure and the first region are of the same conductivity type.
(18) The surface emitting element according to any one of (1) to (17), in which at least one of the first semiconductor structure and the second semiconductor structure includes a reflecting mirror.
(19) The surface emitting element according to any one of (1) to (18), in which the light emitting layer has a plurality of the light emitting regions arranged in an in-plane direction.
(20) The surface emitting element according to (19), in which when two directions intersecting with each other in a plane orthogonal to a stacking direction are referred to as a first direction and a second direction, the substrate and/or the first semiconductor structure includes a plurality of the low resistance regions each extending along the first direction and arranged along the second direction, the second semiconductor structure includes a plurality of the second regions each extending along the second direction and arranged along the first direction, and the light emitting region is located on an intersection of each of the low resistance regions and each of the second regions when viewed from the stacking direction.

### REFERENCE SIGNS LIST

10-1 to 10-4, 20, 20-1 to 20-4, 30, 30-1 to 30-4, 40, 40-1 to 40-4, 50, 60, 70, 80, 90, 110, 120, 130, 140, 150, 160, 170, 180, 190, 210 SURFACE EMITTING ELEMENT
100 Substrate
100a Low resistance region
101 First semiconductor structure
101a, 101a1, 101a2, 112, 113 Low resistance region
102 Second semiconductor structure
102a First region
102b Second region
102b1 Circling portion
102b2 Extending portion
103 Light emitting layer
105 Another low resistance region
109 Still another low resistance region (another low resistance region)
106 Electrode
107 Electrode
111 Oxidation confinement Layer (layer having current confinement region)
M1 First mesa
M2 Second mesa
LS Multilayer structure

1. A surface emitting element comprising:
a multilayer structure including
a first semiconductor structure and a second semiconductor structure stacked with each other, and
a light emitting layer disposed between the first semiconductor structure and the second semiconductor structure and having a light emitting region, wherein
in the second semiconductor structure, at least a surface layer on a side opposite to the light emitting layer side has a first region corresponding to the light emitting region and a second region that is a surrounding region of the first region and has lower resistance than the first region.

2. The surface emitting element according to claim 1, wherein the multilayer structure is provided with a current confinement region for setting the light emitting region.

3. The surface emitting element according to claim 1, wherein the second region has a higher impurity concentration than the first region.

4. The surface emitting element according to claim 1, wherein an electrode is provided on the second region.

5. The surface emitting element according to claim 4, wherein
the second region has an extending portion extending in an in-plane direction from the first region side, and
the electrode is installed on the extending portion.

6. The surface emitting element according to claim 1, wherein the second region has a circling portion surrounding the first region.

7. The surface emitting element according to claim 1, wherein
the multilayer structure includes a substrate disposed on a side opposite to the light emitting layer side of the first semiconductor structure, and
at least a surface layer of the substrate on the first semiconductor structure side and/or at least a surface layer of the first semiconductor structure on the substrate side have a low resistance region.

8. The surface emitting element according to claim 7, wherein the low resistance region has a higher impurity concentration than a surrounding region thereof.

9. The surface emitting element according to claim 7, wherein the low resistance region is provided in a surrounding region of the substrate and/or the first semiconductor structure corresponding to the light emitting region.

10. The surface emitting element according to claim 7, wherein an electrode is provided on the low resistance region.

11. The surface emitting element according to claim 7, wherein the multilayer structure has another low resistance region connected to the low resistance region.

12. The surface emitting element according to claim 11, wherein the another low resistance region has a higher impurity concentration than a surrounding region thereof.

13. The surface emitting element according to claim 11, wherein
the multilayer structure has a mesa on the substrate, the mesa having an electrode placed on a top, and
the another low resistance region extends at least inside the mesa in a stacking direction, and has one end connected to the low resistance region and the other end connected to the electrode.

14. The surface emitting element according to claim 11,
wherein the multilayer structure has a mesa including the light emitting region on the substrate, and
the another low resistance region extends inside the mesa in a stacking direction, and has one end connected to the second region and the other end connected to the low resistance region.

15. The surface emitting element according to claim 11, wherein the low resistance region and the another low resistance region are of the same conductivity type.

16. The surface emitting element according to claim 1, wherein the first region and the second region are of different conductivity types.

17. The surface emitting element according to claim 1, wherein the first semiconductor structure and the first region are of the same conductivity type.

18. The surface emitting element according to claim 1, wherein at least one of the first semiconductor structure and the second semiconductor structure includes a reflecting mirror.

19. The surface emitting element according to claim 7, wherein the light emitting layer has a plurality of the light emitting regions arranged in an in-plane direction.

20. The surface emitting element according to claim 19, wherein when two directions intersecting with each other in a plane orthogonal to a stacking direction are referred to as a first direction and a second direction, the substrate and/or the first semiconductor structure includes a plurality of the low resistance regions each extending along the first direction and arranged along the second direction, the second semiconductor structure includes a plurality of the second regions each extending along the second direction and arranged along the first direction, and the light emitting region is located on an intersection of each of the low resistance regions and each of the second regions when viewed from the stacking direction.
